(19) United States
(12) Patent Application Publication
(10) Pub. No.: US 2025/0366249 A1
(43) Pub. Date: Nov. 27, 2025

(54) SEMICONDUCTOR DEVICES AND METHODS OF FABRICATIMG THE SAME

(71) Applicant: Taiwan Semiconductor Manufacturing Company, Ltd., Hsinchu (TW)

(72) Inventors: Chung-Lei Chen, Hsinchu (TW); Anhao Cheng, Hsinchu (TW); Yen-Liang Lin, Hsinchu (TW)

(73) Assignee: Taiwan Semiconductor Manufacturing Company, Ltd., Hsinchu (TW)

(21) Appl. No.: 19/294,829

(22) Filed: Aug. 8, 2025

Related U.S. Application Data
(63) Continuation of application No. 18/174,413, filed on Feb. 24, 2023.
(60) Provisional application No. 63/409,997, filed on Sep. 26, 2022.

(51) Int. Cl. H10F 39/00; H01L 21/033; H01L 21/266; H01L 21/3065; H10F 39/18

(52) U.S. Cl. CPC H10F 39/807; H01L 21/0332; H01L 21/0337; H01L 21/266; H01L 21/3065; H10F 39/014; H10F 39/8037; H10F 39/184

(57) ABSTRACT

A semiconductor device includes a substrate having a first device and a second device, where at least one of the first device and the second device includes a photo-sensitive element. The semiconductor device includes a first isolation feature surrounding the first device, where the first isolation feature has a first depth. The semiconductor device includes a second isolation feature surrounding the second device, where the second isolation feature has a second depth and where the first depth is greater than the second depth.

### CROSS-REFERENCE TO RELATED APPLICATION

The present application is a continuation of U.S. patent application Ser. No. 18/174,413, filed on Feb. 24, 2023, which claims priority to and the benefit of U.S. Provisional Application No. 63/409,997, filed Sep. 26, 2022, the entire disclosures of each of which are incorporated herein by reference for all purposes.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 9, 10, 17, 24, and 32 each illustrate an example flow chart of a method for fabricating a semiconductor device, in accordance with some embodiments.

FIGS. 2, 3, 4, 5, 6, 7, and 8 illustrate cross-sectional views of an example semiconductor device during various fabrication stages, made by the method of FIG. 1, in accordance with some embodiments.

FIGS. 11, 12, 13, 14, 15, and 16 illustrate cross-sectional views of an example semiconductor device during various fabrication stages, made by the method of FIGS. 9 and/or 10, in accordance with some embodiments.

FIGS. 18, 19, 20, 21, 22, and 23 illustrate cross-sectional views of an example semiconductor device during various fabrication stages, made by the method of FIGS. 9 and/or 17, in accordance with some embodiments.

FIGS. 25, 26, 27, 28, 29, 30, and 31 illustrate cross-sectional views of an example semiconductor device during various fabrication stages, made by the method of FIGS. 9 and/or 24, in accordance with some embodiments.

FIGS. 33, 34, 35, 36, 37, and 38 illustrate cross-sectional views of an example semiconductor device during various fabrication stages, made by the method of FIGS. 9 and/or 32, in accordance with some embodiments.

FIG. 39 illustrates a top view of an example semiconductor device, in accordance with some embodiments.

FIG. 40 illustrates a cross-sectional view along line AA′ of the example semiconductor device of FIG. 39, in accordance with some embodiments.

FIG. 41 illustrates a top view of an example semiconductor device, in accordance with some embodiments.

FIG. 42 illustrates a cross-sectional view along line BB′ of the example semiconductor device of FIG. 41, in accordance with some embodiments.

FIG. 43 illustrates a top view of an example semiconductor device, in accordance with some embodiments.

FIG. 44 illustrates a top view of an example semiconductor device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As technologies evolve, charge-sensitive devices such as complementary metal-oxide semiconductor (CMOS) image sensors are gaining popularity over traditional charged-coupled devices (CCDs) due to certain advantages inherent in the CMOS image sensors. In particular, a CMOS image sensor (CIS) may have a high image acquisition rate, a lower operating voltage, lower power consumption and higher noise immunity. In addition, CMOS image sensors may be fabricated on the same high volume wafer processing lines as logic and memory devices. As a result, a CMOS image chip may comprise both image sensors and all the necessary logics such as amplifiers, A/D converters and the like.

CMOS image sensors are pixelated metal oxide semiconductor devices. A CIS may typically include an array of photo-sensitive pixel units (sometimes referred to as picture elements), each of which may include a number of transistors (e.g., a switching transistor and reset transistor), capacitors, and a photo-sensitive device (e.g., a photodiode), where the photo-sensitive device may be sensitive to light of different wavelengths in the visible spectrum, the infrared spectrum, or the like. A CMOS image sensor utilizes light-sensitive CMOS circuitry to convert photons into electrons. The photo-sensitive CMOS circuitry typically includes a photodiode formed in a silicon substrate. As the photodiode is exposed to light, an electrical charge is induced in the photodiode. Each pixel may generate electrons proportional to the amount of light that falls on the pixel when light is incident on the pixel from a subject scene. Furthermore, the electrons are converted into a voltage signal in the pixel and further transformed into a digital signal through a number of logic circuits (e.g., an analog-to-digital converter (ADC) circuit, a digital-to-analog converter (DAC) circuit, etc.). A plurality of other logic circuits (e.g., a static random access memory (SRAM) circuit, a controller, a buffer storage, etc.) may receive the digital signals and process them to display an image of the subject scene.

A CIS may include a number of transistors (e.g., transfer gate transistors, reset transistors) in the logic circuits that are typically fabricated based on CMOS technologies. Shallow-trench isolation (STI) structures are widely used to maintain and/or improve device operations, especially for charge-sensitive devices such as CISs. An STI structure may be designed to isolate adjacent conductive element (e.g., CIS pixel units) and may be generally formed by etching (e.g., by a dry or plasma etching process) a semiconductor substrate to form a trench and depositing a dielectric (or insulating) material to fill the trench. While existing STI technologies have been generally adequate in addressing various technical challenges, they have not been entirely satisfactory in all aspects. For example, depth of an STI structure may be an important factor in CIS design due to its influence on phenomena such as dark current and crosstalk. Dark current, which may be on the order of about 1E-17 A, is related to the presence of current leakage in a totally dark environment and may be responsible for degraded imaging results. Dark current, on a device-structure level, may be caused by damages arising from the etching of the trench during the formation of an STI structure. In this regard, reducing the depth of the trench during the etching process may reduce dark current. However, such practice may lead to increased crosstalk (e.g., spectral, optical, or electrical crosstalk) between adjacent photo-sensitive devices. Accordingly, it remains desirable to improve designs of STI structures for at least these reasons.

The present disclosure provides embodiments of a semiconductor structure (or device) including STI structures of various depths, where the STI structures may be configured to provide isolation between devices within a CIS, such as between photo-sensitive devices (e.g., pixel units each including at least a photodiode) in a pixel region and/or between logic devices (e.g., transistors) in a peripheral circuit region adjacent to the pixel region, for example. In addition, embodiments of the present disclosure may be applicable to other charge-sensitive devices, system-on-chip devices (SOCs), memory devices, or the like.

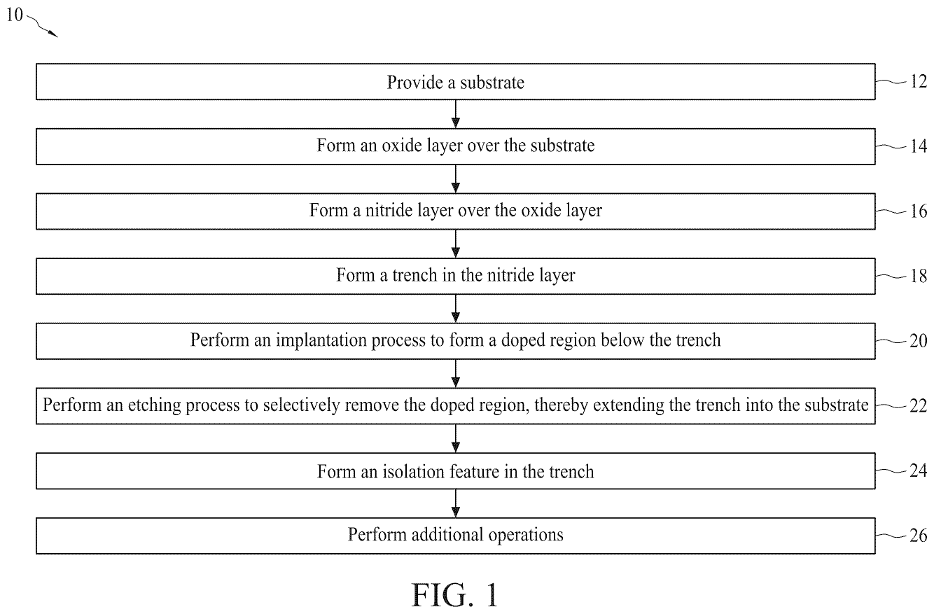

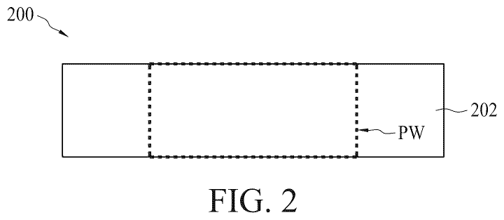

FIG. 1 is a flowchart illustrating a method 10 for fabricating a semiconductor structure 200, according to various aspects of the present disclosure. FIGS. 2-8 show schematic cross-sectional views of the semiconductor structure 200 at various stages of fabrication according to an embodiment of the method 10 of FIG. 1. The semiconductor structure 200 may be included in an image sensor, such as a CIS, a microprocessor, memory device, and/or other integrated circuit (IC). It is noted that the method of FIG. 1 does not produce a completed semiconductor structure 200. A completed semiconductor structure 200 may be fabricated using CMOS technology processing. Accordingly, it is understood that additional steps may be provided before, during, and after the method 10 of FIG. 1, and that some other steps may only be briefly described herein. In one example, a step of forming a photo-sensitive device, such as a photodiode, may be implemented before, during and/or after the method 10. Also, FIGS. 2-8 are simplified for a better understanding of the present disclosure. For example, although the figures illustrate the semiconductor structure 200, it is understood the IC may include a number of other components such as, for example, transistors, resistors, capacitors, inductors, fuses, etc.

Referring to FIGS. 1 and 2, the method 10 begins at operation 12 in which a substrate 202 is provided, in accordance with various embodiments.

The substrate 202 may be a semiconductor substrate, such as a bulk semiconductor, a semiconductor-on-insulator (SOI) substrate, or the like, which may be doped (e.g., with a p-type or an n-type dopant) or un-doped. The substrate 202 may be a wafer, such as a silicon wafer. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 202 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

In some embodiments, the substrate 202 includes an eptiaxially-grown (epi) semiconductor layer, such as a silicon layer (also referred to as an epi layer), over an insulator layer described above. The epi semiconductor layer may be further doped with a dopant species, such as a p-type dopant species including boron, BF₂, the like, or combinations thereof, or an n-type dopant including phosphorous, arsenic, antimony, the like, or combinations thereof.

In some embodiments, the substrate 202 includes doped regions (or wells) containing impurities such as p-type dopants or n-type dopants. For example, as depicted in FIG. 1, one or more p-type doped regions (PWs) may be formed in the substrate 202, where each p-type doped region may include a p-type dopant, such as boron, BF₂, the like, or combinations thereof. Alternatively or additionally, the substrate 202 may include one or more n-type doped regions, or n-wells NWs, where each n-type doped region may include an n-type dopant, such as phosphorous, arsenic, antimony, the like, or combinations thereof. For embodiments in which the substrate 202 includes a doped epi layer over an insulator layer, where the doped epi layer includes a dopant at a first concentration (or dosage), the doped regions (e.g., the PWs) may include the same dopant species at a second concentration different from the first concentration.

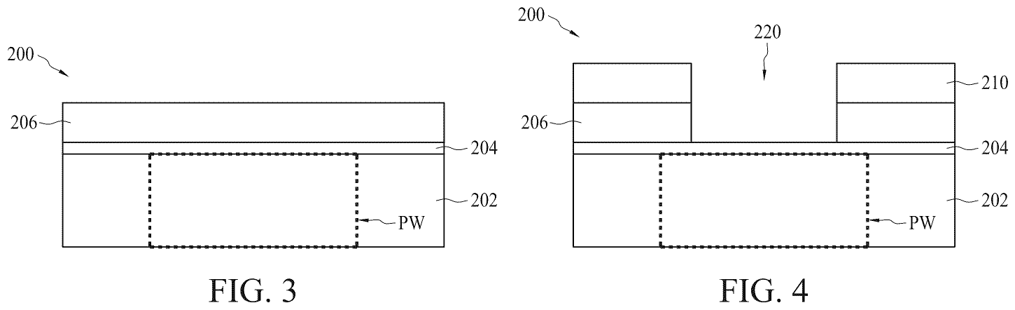

Referring to FIGS. 1 and 3, the method 10 continues to operation 14 in which an oxide layer (alternatively referred to as a pad oxide layer) 204 is formed over the substrate 202.

In some embodiments, the oxide layer 204 includes an oxide material, such as silicon oxide, for example. The oxide layer 204 may be formed using any suitable process, such as a thermal oxidation process, a chemical oxidation process, a deposition process (e.g., by chemical vapor deposition (CVD), atomic layer deposition (ALD), or the like. The oxide layer 204 may act as an adhesion layer between the substrate 202 and a subsequently-formed nitride layer.

Still referring to FIGS. 1 and 3, the method 10 continues to operation 16 in which a nitride layer (alternatively referred to as a pad nitride layer) 206 is formed over the oxide layer 204.

In some embodiments, the nitride layer 206 includes a nitride material, such as silicon nitride, silicon oxynitride, silicon carbonitride, the like, or combinations thereof. The nitride layer 206 may be formed using any suitable process, such as CVD, ALD, or the like. In some embodiments, the oxide layer 204 and the nitride layer 206 together serve as a hard mask layer to protect portions of the substrate 202 during subsequent etching processes.

Referring to FIGS. 1 and 4, the method 10 continues to operation 16 in which a patterned mask layer 210 including an opening is formed over the nitride layer 206 to expose a portion of the nitride layer 206.

The patterned mask layer 210 may be formed by patterning a mask layer using photolithography techniques. Generally, photolithography techniques utilize a photoresist material (not shown) that is deposited, irradiated (exposed), and developed to remove portions of photoresist material and form a pattern therein. Remaining portions photoresist material protect the underlying material, such as the nitride layer 206 in the present embodiment, from subsequent processing steps, such as etching processes. For example, the photoresist material is patterned to form the patterned mask layer 210 over the nitride layer 206, as depicted in FIG. 4.

Subsequently, still referring to FIGS. 1 and 4, the method 10 continues to operation 18 in which the nitride layer 206 is etched using the patterned mask layer 210 as an etch mask, resulting in a trench (or opening) 220 in the nitride layer 206.

The nitride layer 206 may be etched by any suitable process, such as a dry etching process, a wet etching process, the like, or combinations thereof. In one example, the nitride layer 206 may be etched by a wet etching process using phosphorous acid. In some embodiments, the etching process is configured to selectively remove the nitride layer 206 without removing, or substantially removing, the underlying oxide layer 204. In this regard, the trench 220 exposes a portion of the oxide layer 204 as depicted in FIG. 4. In some embodiments, the trench 220 exposes a p-well (PW) formed in the substrate 202. After performing the etching process, the patterned mask layer 210 is removed from the nitride layer 206 by a suitable process, such as plasma ashing or resist stripping.

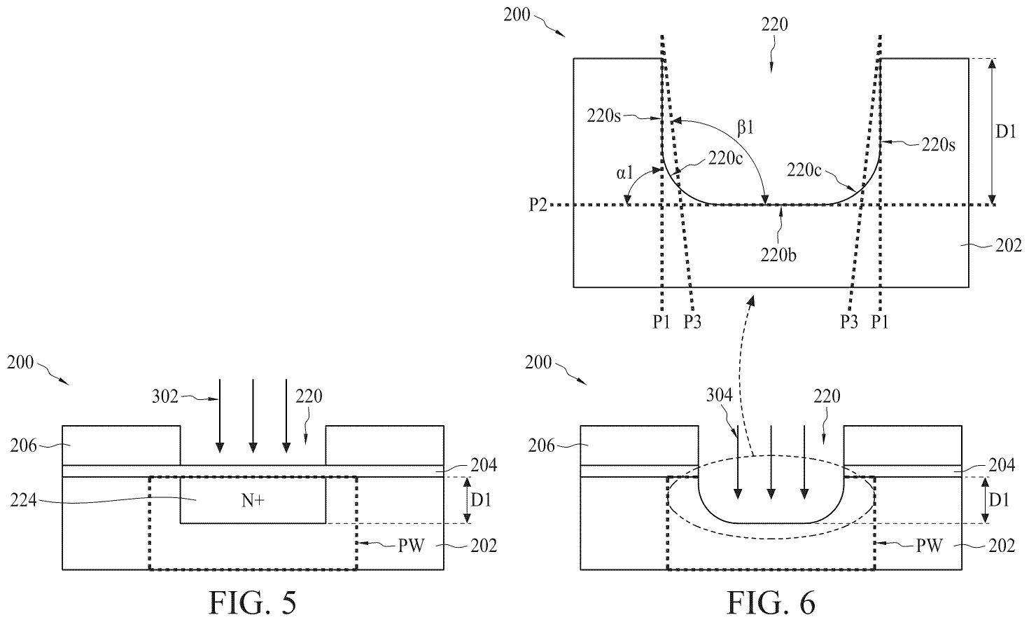

Referring to FIGS. 1 and 5, the method 10 continues to operation 20 in which an implantation process (or doping process) 302 is performed in the trench 220 to form a doped region (or doped layer) 224 in a top portion of the substrate 202.

The implantation process 302 may be an ion implantation process, for example, configured to dope the portion of the substrate 202 exposed in the trench 220 with a dopant species. In some embodiments, the dopant includes an n-type dopant, such as arsenic, phosphorous, antimony, the like, or combinations thereof. In some embodiments, a dosage (or concentration) of the dopant species implemented at the implantation process 302 is at least about 1E19 cm⁻² and less than about 1E21 cm⁻². Significance of such a dosage range is discussed in detail below.

In some embodiments, the doped region 224 is formed in the top portion of the substrate 202 below the oxide layer 204, where a depth (or thickness) D1 of the doped region 224 measured from a top surface of the substrate 202 is less than about 4000 Å, such as about 1500 Å or about 3000 Å. In some embodiments, the implantation process 302 is implemented with an implantation energy ranging from about 10 keV to about 30 keV. In some embodiments, an anneal process (e.g., a rapid thermal anneal process) is performed after performing the implantation process 302 to active the n-type dopant, for example. The anneal process may be implemented at a temperature of about 950° C.

In some embodiments, the doped region 224, which includes an n-type dopant, is formed in the PW of the substrate 202, which includes a dopant of a different type, such as a p-type dopant. In some embodiments, a difference in composition between the doped region 224 and the PW results in an etching selectivity therebetween, such that the doped region 224 may be etched without etching, or substantially etching, the PW of the substrate 202. As will be discussed in detail below, the depth D1 corresponds to a depth of the trench 220 extended into the substrate 202 (e.g., the PW) for subsequently forming an isolation (e.g., STI) feature (e.g., isolation feature 232 depicted in FIG. 8) therein. Therefore, depending on a desired depth of the resulting isolation feature, the depth D1 may be configured accordingly by adjusting one or more implantation process 302, such as the implantation energy.

Referring to FIGS. 1 and 6, the method 10 continues to operation 22 in which the doped region 224 is removed by an etching process 304, thereby vertically extending the trench 220 into the substrate 202.

In the present embodiments, the etching process 304 is a chemical etching process, such as a reactive ion etching (RIE) process, during which an etchant is applied to selectively remove the doped region 224 without removing, or substantially removing, the substrate 202 (e.g., the PW) and the nitride layer 206. In some embodiments, the etching process 304 is implemented using a halogen-containing etchant, such as a chlorine-containing etchant (e.g., Cl₂), a bromine-containing etchant (e.g., Br₂), the like, or combinations thereof. In some embodiments, the etchant used does not include any fluorine-containing material. In an example embodiment, the etchant includes chlorine gas Cl₂. In some embodiments, the etching process 304 first removes a portion of the oxide layer 204 exposed in the trench 220. In the present embodiments, the etching process 304 stops, or spontaneously stops in some instances, when an entirety of the doped region 224 is removed, thereby exposing portions of the substrate 202 in the trench 220. In this regard, a bottom surface of the trench 220 approximately corresponds to a bottom surface of the doped region 224, such that a depth of a portion of the trench 220 disposed in the substrate 202 is defined by the depth D1.

In some embodiments, the n-type dopant provided by the implantation process 302 can increase concentration of free electron carriers and can reduce the energy barrier for charge transfer to adsorbed (e.g., chemisorbed) etchant atoms (e.g., chlorine and/or bromine atoms). For example, without the n-type dopant, steric hindrance can make it difficult for the etchant atoms to adsorb onto and penetrate into a substantially neutral silicon surface (e.g., regions of the substrate 202 not doped with an n-type dopant), resulting in a low etching rate. In contrast, n-type doping implemented by the implantation process 302, for example, can help facilitate charge transfer from the doped silicon atoms to the adsorbed etchant atoms, thereby lowering the steric hindrance for additional etchant atoms to adsorb onto and penetrate into the doped silicon surface (e.g., in the doped region 224), leading to an increased etching rate. The following equation describes an example relationship between the etching rate (ER) and concentration (or dosage) of the n-type dopant (Nₑ), concentration of the etchant Cl₂ (n_{Cl}), and temperature (T), among other factors:

$$ER = {vN}_{e}^{γ} {n}_{Cl} {T}^{1 / 2} {e}^{{E}_{a} / kT}$$

In this regard, the ER increases with increasing concentration of the n-type dopant and increasing concentration of the etchant (e.g., Cl₂).

In some embodiments, an amount (e.g., a trace amount) of the n-type dopant introduced by the implantation process 302 remains in the vicinity of the trench 220 after performing the etching process 304. Such amount is generally much less than the dosage of the n-type dopant introduced by the implantation process 302. In this regard, the n-type dopant may be detected in or near sidewalls of the trench 220 along the depth D1 and/or along a bottom surface of the trench 220. In some embodiments, the n-type dopant may be detected at a depth less than the depth D1. For example, the n-type dopant may be detected at a depth of less than 4000 Å below a top surface of the substrate 202. For embodiments in which the dosage of the n-type dopant is in the range of about 1E19 cm⁻² to about 1E21 cm⁻², the amount remaining in the vicinity of the trench 220 after performing the etching process 304 may be less than about 1E17 cm⁻² (e.g., about 1E13 cm⁻² to about 1E15 cm⁻²).

In the present embodiments, a ratio of an etching rate of the doped region 224 to an etching rate of the un-doped region (e.g., containing less than about 1E17 cm⁻² of an n-type dopant, such as the PW and other portions of the substrate 202) in the substrate 202 may be about 6 to about 100, which is provided by the dosage range of about 1E19 cm⁻² and about 1E21 cm⁻² introduced at the implantation process 302. Such ratio numerically describes the etching selectivity between the doped region 224 and the surrounding regions not doped with the n-type dopant. On one hand, a dosage of less than about 1E19 cm⁻² (e.g., the etching selectivity being less than about 6) may not be sufficient to avoid inadvertent over-etching of the substrate 202 to provide a sufficiently deep. On the other hand, a dosage of greater than about 1E21 cm⁻² (e.g., the etching selectivity being greater than about 100) may become difficult to control for achieving a desired profile in the resulting trench 220. In some examples, the etching rate of the doped region 224 may be about 6 Å/s to about 10 Å/s, and the etching rate of the un-doped region may be about 0.1 Å/s to about 1 Å/s.

As shown in an enlarged view of a portion of the semiconductor structure 200, the trench 220 may be defined by sidewalls 220s, a bottom surface 220b, and corners 220c each connecting the sidewall 220s with the bottom surface 220b. In the present embodiments, the sidewalls 220s extend vertically, or substantially vertically, along a vertical plane P1, and the bottom surface 220b extends horizontally, or substantially horizontally, along a horizontal plane P2, where P1 and P2 are substantially perpendicular to one another. In this regard, forming the trench 220 in the substrate 202 by the selective removal of the doped region 224 using the etching process 304 (e.g., selective of the doped region 224 to the substrate 202) results in the substantially vertically sidewalls 220s with respect to the bottom surface 220b, such that an angle α1 between the planes P1 and P2 is approximately 90°. In contrast, forming an opening in the substrate 202 by removing a portion of the substrate 202 rather than the doped region 224 using a non-selective etching process generally results in slanted sidewalls along a plane P3 with respect to the bottom surface 220b, such that an angle β1 between the planes P3 and P2 is greater than 90° (e.g., the resulting trench has an inverted trapezoidal shape). Accordingly, the trench 220 formed by the etching process 304 as shown in FIG. 6 (and the enlarged portion thereof) can be defined by a more isotropic profile in contrast to the profile of a trench formed by a non-selective etching process. Additionally, due to the selective nature of the etching process 304, the depth of the trench 220 corresponds to the depth D1 of the doped region 224. In some embodiments, the corners 220c of the trench 220 may be rounded and defined by a curvature rather than a sharp angle (e.g., the angle α1).

Subsequently, referring to FIGS. 1, 7, and 8, the method 10 continues to operation 24 in which an isolation feature (or isolation structure) 232 is formed in the trench 220.

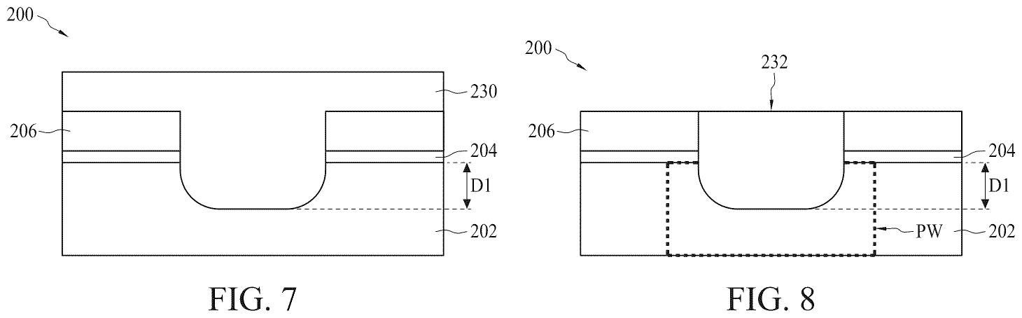

Referring to FIG. 7, a dielectric layer 230 may be first deposited to fill the trench 220, where portions of the dielectric layer 230 may be formed over a top surface of the nitride layer 206. The dielectric layer 230 may be a single-layered structure as depicted or may be a multi-layered structure including different dielectric materials. The dielectric layer 230 may include any suitable material, such as silicon oxide, carbon-doped silicon oxide, a comparatively low dielectric constant (k value) dielectric material with a k value less than about 4.0, the like, or combinations thereof. In some examples, the dielectric layer 230 may include a low-k (e.g., k≤3.0) material, an extreme low-k (e.g., k≤2.5) material, and/or a porous low-k (e.g., k≤2.0) material, such as spin-on inorganic dielectrics, spin-on organic dielectrics, porous dielectric materials, organic polymer, organic silica glass, FSG (SiOF series material), HSQ (hydrogen silsesquioxane) series material, MSQ (methyl silsesquioxane) series material, or porous organic series material. The dielectric layer 230 may be deposited using any suitable process, such as CVD, PVD, ALD, remote plasma enhanced CVD (RPECVD), flowable CVD (FCVD), spin-on-coating, the like, or combinations thereof.

Subsequently, referring to FIG. 8, the dielectric layer 230 is planarized using a suitable process, such as a chemical-mechanical polishing (or planarizing; CMP) process to remove the portions of the dielectric layer 230 formed over the nitride layer 206. The resulting isolation feature 232 includes a top surface that is substantially coplanar with the nitride layer 206.

Referring to FIG. 1, the method 10 continues to operation 26 in which additional operations (not depicted) may be performed to the semiconductor structure 200 including the isolation feature 232. In one example, an etching process may be performed to selectively remove the nitride layer 206 from the oxide layer 204, thereby exposing sidewalls of the isolation feature 232. Additionally or alternatively, one or more semiconductor devices, such as a photo-sensitive device and/or a transistor, may be formed over a region of the substrate 202 adjacent to the isolation feature 232, such that the isolation feature 232 electrically isolates or separates the device from an adjacent device to prevent shorting therebetween. For example, devices suitable for forming a CIS or a portion thereof (e.g., a pixel unit), including at least one photo-sensitive device coupled to at least one transistor, may be isolated using the isolation feature 232, as will be discussed in detail below. In some embodiments, the substrate 202 may be processed according to the method 10 provided herein, for example, to form a plurality of isolation features 232.

Accordingly, the present disclosure provides embodiments in which the profile and depth of a trench in which an isolation feature, such as an STI structure (or STI feature), is formed may be controlled by forming a doped region in the substrate, where a depth of the doped region corresponds to the depth of the trench, and performing a selective etching process to remove the doped region with respect to the substrate. The resulting trench may be defined by substantially straight sidewalls. Additionally, the depth of the trench, and thus the depth of the resulting isolation feature, may be more precisely tuned according to design requirements of the devices formed adjacent thereto. For example, an isolation feature adjacent to a photo-sensitive device capable of detecting wavelengths on the visible spectrum may be tuned to a shallower depth, while an isolation feature adjacent to a photo-sensitive device capable of detecting wavelengths on the infrared (IR) spectrum may be tuned to a greater depth. In some examples, an isolation feature having a shallower depth may reduce dark current of an imaging device (e.g., a CIS).

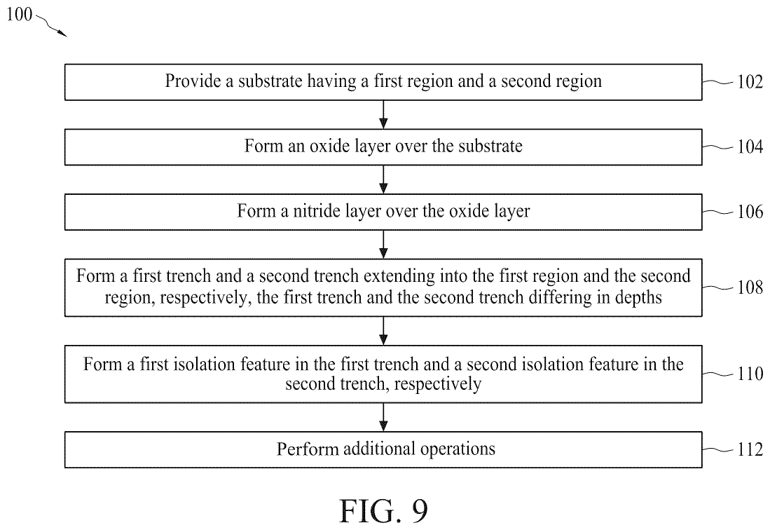

Now referring to FIGS. 9-38 collectively, the present disclosure provides various embodiments of forming semiconductor structures each having more than one isolation (e.g., STI) features similar to the isolation feature 232 and configured to provide isolation for devices of a CIS, for example.

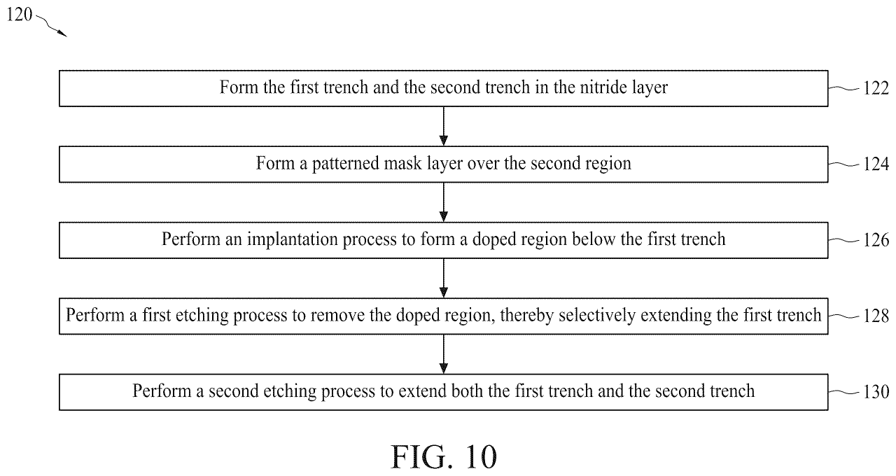

FIG. 9 is a flowchart illustrating a method 100 for fabricating semiconductor structures 400, 600, 800, and/or 1000, according to various aspects of the present disclosure. The semiconductor structures 200 400, 600, 800, and/or 1000 may be included in an image sensor, such as a CIS, a microprocessor, memory device, and/or other integrated circuit (IC). It is noted that the method 100 of FIG. 9 does not produce a completed semiconductor structure 200 400, 600, 800, and/or 1000, which may be fabricated using CMOS technology processing. Accordingly, it is understood that additional steps may be provided before, during, and after the method 100 of FIG. 9, and that some other steps may only be briefly described herein. In one example, a step of forming a photo-sensitive device, such as a photodiode, may be implemented before, during, and/or after the method 100. For example, although the figures illustrate the semiconductor structures 400, 600, 800, and/or 1000, it is understood the IC may include a number of other components such as, for example, transistors, resistors, capacitors, inductors, fuses, etc. In some embodiments, operation 108 of the method 100 may be implemented by any of methods 120, 140, 160, and 180 described in FIGS. 10, 17, 24, and 32, respectively.

In general, the method 100 may begin with an operation 102 in which a substrate (e.g., substrate 402, 602, 802, or 1002) having a first region (e.g., region 402a, 602a, 802a, or 1002a) and a second region (e.g., region 402b, 602b, 802b, or 1002b) is provided. The method 100 may continue to operation 104 in which an oxide layer (e.g., oxide layers 404, 604, 804, or 1004) is formed over the substrate. The method 100 may continue to operation 106 in which a nitride layer (e.g., nitride layer 406, 606, 806, or 1006) is formed over the oxide layer. The method 100 may continue to operation 108 in which a first trench (e.g., trench 420a, 620a, 820a, or 1020a) and a second trench (e.g., trench 420b, 620b, 820b, or 1020b) are formed to extend into the first region and the second region, respectively, where the first trench and the second trench differ in depths. The method 100 may continue to operation 110 in which a first isolation feature (e.g., isolation feature 432, 632, 832, or 1032) and a second isolation feature (e.g., isolation feature 434, 634, 834, or 1034) are formed in the first trench and the second trench, respectively. The method 100 may subsequently continue to operation 112 in which additional operations are performed. In one example, the nitride layer may be removed from the oxide layer, such that the first isolation feature and the second isolation feature protrude from the oxide layer. Additionally or alternatively, one or more semiconductor devices, such as a photo-sensitive device and/or a transistor device, may be formed over a region of the substrate adjacent to the first and/or the second isolation features, such that the first and/or the second isolation features electrically isolate or separate the device from an adjacent device to prevent shorting therebetween.

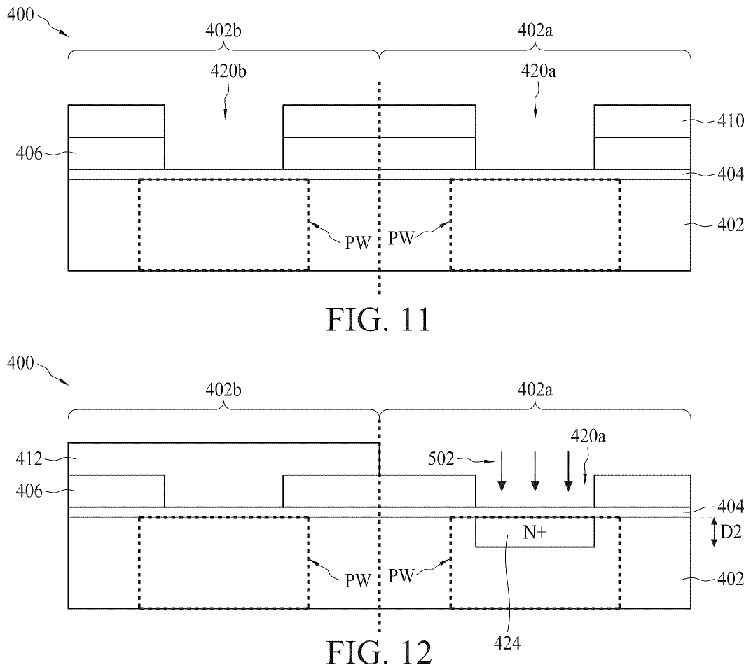

In some embodiments, FIGS. 11-16 illustrate schematic cross-sectional views of the semiconductor structure 400 at various stages of fabrication according to the methods 100 and 120.

Referring to FIGS. 9 and 11, the method 100 begins with operation 102 in which a substrate 402 is provided in the semiconductor structure 400, where the substrate 402 includes a region 402a and a region 402b. The substrate 402 may be similar to the substrate 202 as described above. Although the regions 402a and 402b are depicted to be adjacent to one another, they are not limited as such. For example, the regions 402a and 402b may be separated by one or more intervening regions. In some embodiments, each of the regions 402a and 402b includes a PW, which may be similar to the PW of the substrate 202 as described above. In some embodiments, the regions 402a and 402b are or include regions configured to provide different portions of a semiconductor device, such as a charge-sensitive device. In some embodiments, the region 402b may be configured to provide a pixel region of a charge-sensitive device (e.g., a CIS), which may include an array of pixel units each having a photo-sensitive device (e.g., a photodiode), and the region 402a may be configured to provide a peripheral circuit region of the charge-sensitive device, which may include one or more logic devices (e.g., transistors), where the regions 402a and 402b are electrically coupled with one another. In some embodiments, the regions 402a and 402b may be configured to provide different pixel regions of the same charge-sensitive device, such that they include different types of photo-sensitive devices. For example, the region 402b may be configured to provide a photo-sensitive device capable of detecting visible light and the region 402a may be configured to provide a photo-sensitive device capable of detecting IR light.

Still referring to FIGS. 9 and 11, the method 100 then continues to operation 104 in which an oxide layer 404 is formed over the substrate 402, covering both the regions 402a and 402b, where the oxide layer 404 may be similar to the oxide layer 204 in composition and formed in a manner similar to that described above. The method 100 then continues to operation 106 in which a nitride layer 406 is formed over the oxide layer 404, where the nitride layer 406 may be similar to the nitride layer 206 in composition and formed in a manner similar to that described above.

Referring to FIG. 9, the method 100 continues to operation 108 in which a trench 420a and a trench 420b are formed in the regions 402a and 402b, respectively. Operation 108 may be implemented by the method 120 described in FIGS. 10-16.

Referring to FIGS. 10 and 11, the method 120 begins with operation 122 in which the trenches 420a and 420b are formed in the nitride layer 406. The trenches 420a and 420b may be formed by a series of patterning and etching processes similar to those described above with respect to forming the trench 220. For example, forming the trenches 420a and 420b may include first forming a patterned mask layer 410 that includes openings corresponding to the trenches 420a and 420b over the nitride layer 406, thereby exposing portions of the nitride layer 406. The patterned mask layer 410 may be similar to the patterned mask layer 210 in composition and formed in a manner similar to that described above. Subsequently, the exposed portions of the nitride layer 406 are removed by an etching process (e.g., a dry etching process or a wet etching process) using the pattern mask layer 410 as an etch mask and a method similar to that of forming the trench 220 in the nitride layer 206 described above. The resulting patterned nitride layer 406 exposes the oxide layer 404 in the trenches 420a and 420b, respectively. Subsequently, the patterned mask layer 410 may be removed from the regions 402a and 402b by a suitable process, such as plasma ashing or resist stripping.

Referring to FIGS. 10 and 12, the method 120 continues with operation 124 in which a patterned mask layer 412 is selectively formed over the region 402b, thereby filling the trench 420b but exposing the trench 420a. The patterned mask layer 412 may be similar to the patterned mask layer 210 in composition and formed in a manner similar to that described above. In the present embodiments, the patterned mask layer 412 is configured to protect the region 402b during the subsequent processes.

Referring to FIGS. 10 and 12, the method 120 continues with operation 126 in which an implantation process 502 is performed to form a doped region (or doped layer) 424 below the oxide layer 404 corresponding to the trench 420a.

In the present embodiments, the implantation process 502 is similar to the implantation process 302 as described above. For example, the implantation process 502 may be an ion implantation process configured to dope the region 402a (e.g., in the PW of the substrate 402) of the substrate 402 with an n-type dopant, such as arsenic, phosphorous, antimony, the like, or combinations thereof. Various parameters (e.g., implantation energy, dosage of the dopant species, etc.) of the implantation process 502 may be similar to those of the implantation process 302 described above. In some embodiments, the doped region 424 and the region 402b (e.g., including the PW) differ in the amount (or concentration) of the n-type dopant, such that an etching selectivity exists therebetween. The doped region 424 may be formed to a depth D2, which extends over a region of the substrate 402 below the oxide layer 404. As described above with respect to the doped region 224, the depth D2 corresponds to the depth of a subsequently-formed trench in the substrate 402. Subsequently, the patterned mask layer 412 may be removed from the region 402b by a suitable process, such as plasma ashing or resist stripping.

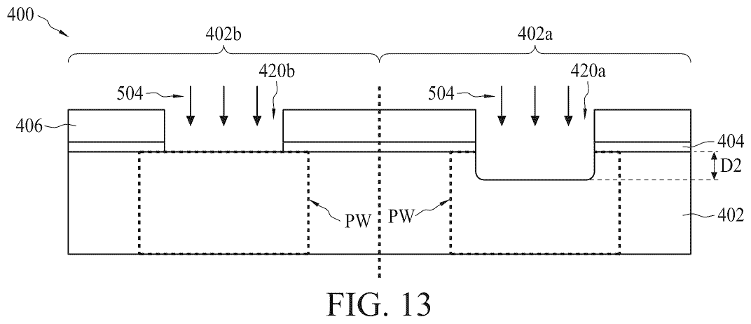

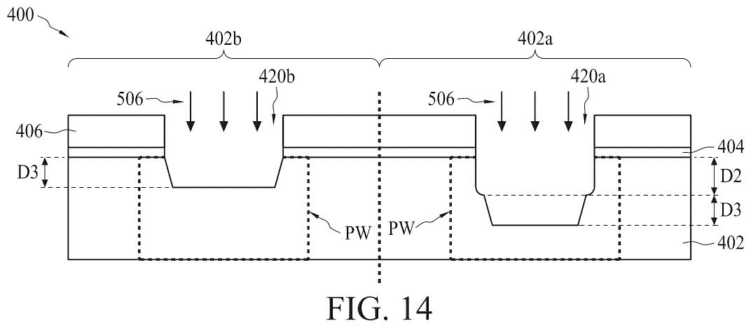

Referring to FIGS. 10 and 13, the method 120 continues with operation 128 in which an etching process 504 is performed to selectively remove the doped region 424 from the region 402a, thereby extending the trench 420a.

In the present embodiments, the etching process 504 is a selective etching process similar to the etching process 304 as described above. For example, the etching process 504 is a chemical etching process (e.g., an RIE process) in which an etchant is applied to selectively react with and subsequently remove the doped region 424 without removing, or substantially removing, the surrounding portions of the substrate 402 (e.g., the PW). In this regard, the etching process 504 is configured to selectively remove the doped region 424 exposed in the trench 420a without etching, or substantially etching, the portion of the substrate 402 exposed in the trench 420b, thereby selectively extending the trench 420a into the substrate 402 in the region 402a by the depth D2. As described in detail above with respect to the etching process 304, the etching process 504 stops (or spontaneously stops) when the doped region 424 is consumed, such that the depth of the extended trench 420a corresponds to the depth D2 of the doped region 424. A profile of the resulting trench 420a is similar to that depicted and described with respect to FIG. 6.

Referring to FIGS. 10 and 14, the method 120 continues with operation 130 in which an etching process 506 is performed to extend both the trenches 420a and 420b.

In the present embodiments, the etching process 506 is configured to remove portions of the substrate 402 (e.g., the PW) in the regions 402a and 402b, thereby downwardly extending both the trenches 420a and 420b into the substrate 402. In other words, the etching process 506 is not selective towards either of the two regions 402a and 402b. As shown in FIG. 14, both of the trenches 420a and 420b are extended downward by a depth D3, such that a total depth of the trench 420a is a sum of the depths D2 and D3 and a total depth of the trench 420b is substantially equivalent to the depth D3. The present embodiments do not limit the magnitude of the depths D2 and D3, which may be configured according to specific design requirements. In some embodiments, the depth D3 may be controlled by adjusting the duration of the etching process 506 or a time end-point mechanism. This mechanism differs from the etching process 504, which stops (or spontaneously stops) when the doped region 424 is completely consumed.

In some embodiments, the etching process 506 is a dry etching process distinct from the chemical etching process (i.e., the etching process 504). In this regard, the etching process 506 may remove the substrate 402 in a more anisotropic (or less isotropic) manner than the manner by which the etching process 504 removes the doped region 424. A more anisotropic etching process may result in opposing sidewalls of the trench 420b and opposing sidewalls of at least a bottom portion of the trench 420a to be tapered or slanted toward one another, rather than to remain vertical, or substantially vertical, with respect to a bottom surface of the trenches 420b and 420a, respectively. In some embodiments, the etching process 506 is implemented using plasma that contains a fluorine-based material, such as F₂, CF₄, C₂F₆, C₃F₈, SF₆, SiF₄, NF₃, CIF₃, the like, or combinations thereof. In some embodiments, the plasma additionally includes oxygen (O₂). In some examples, the trench 420b and the bottom portion of the trench 420a may be formed to an inverted trapezoidal shape. In the present embodiments, as will be described in detail below, the etching process 504 and the etching process 506 create different profiles along sidewalls of the trench 420a.

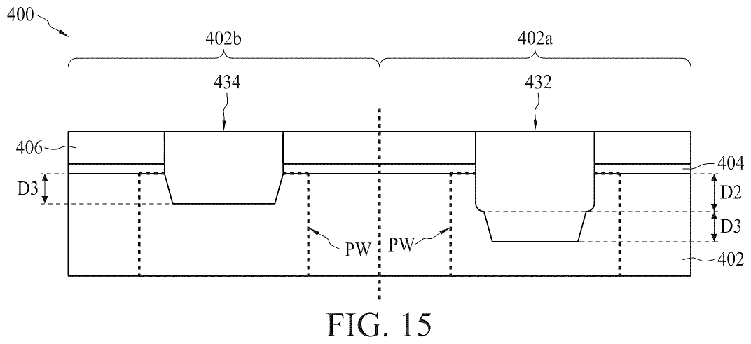

Referring to FIGS. 9 and 15, the method 100 continues with operation 110 in which an isolation feature 432 is formed in the trench 420a and an isolation feature 434 is formed in the trench 420b.

The isolation features 432 and 434 may be similar to the isolation feature 232 in composition and formed in a manner similar to that described above. For example, forming the isolation features 432 and 434 may include depositing a dielectric layer over the semiconductor structure 400 to fill the trenches 420a and 420b and performing a CMP process to planarize a top surface of the dielectric layer with a top surface of the nitride layer 406. The resulting isolation feature 432 has a depth that is the sum of the depths D2 and D3 and the isolation feature 434 has a depth that is substantially equivalent to the depth D3.

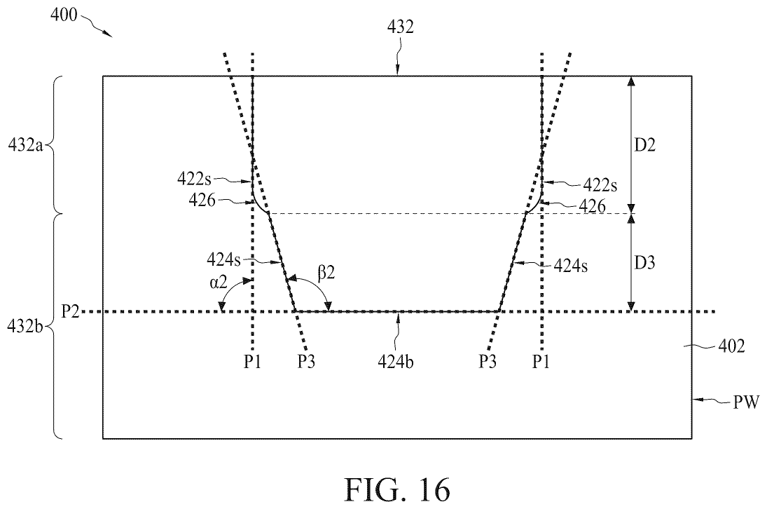

FIG. 16 is an enlarged view of a portion of the semiconductor structure 400 including the isolation feature 432 as shown in FIG. 15. The isolation feature 432 includes a top portion 432a over a bottom portion 432b having different sidewall profiles as a result of the different etching processes used to form them. For example, the top portion 432a is formed by the etching process 504, which is similar to the etching process 304, and the bottom portion 432b is formed by the etching process 506. The etching process 504 is selective to remove the doped region 424 and not, or not substantially, the substrate 402. Hence, profile of the top portion 432a may be defined by vertical sidewalls 422s. As shown, the vertical sidewalls 422s extend along the plane P1, a bottom surface 424b extends along the plane P2, and slanted sidewalls 424s extend along the plane P3. In this regard, the planes P1 and P2 form an angle α2, which is approximately 90°, indicating that the vertical sidewalls 422s are substantially perpendicular to the bottom surface 424b of the isolation feature 432. Profile of the bottom portion 432b may be defined by the slanted sidewalls 424s, where an angle β2 between the planes P2 and P3 is approximately greater than 90°. In some embodiments, the top portion 432a laterally protrudes beyond the slanted sidewalls 424s, such that the isolation feature 432 laterally expands near an interface between the top portion 432a and the bottom portion 432b. In some embodiments, the top portion 432a includes two bottom corners 426 that are rounded, similar to the corners 220c depicted in FIG. 6.

In some embodiments, an amount of the n-type dopant introduced by the implantation process 502 remains in the vicinity of the trench 420a after performing the etching process 506. For example, the n-type dopant may be detected in or near the vertical sidewalls 422a along the depth D2 and/or the bottom surface 424b of the trench 420a. In some embodiments, the n-type dopant may be detected at a depth less than the depth D2. For example, the n-type dopant may be detected at a depth of less than 4000 Å below a top surface of the substrate 202.

Referring to FIG. 9, the method 100 continues with operation 112 in which additional operations (not depicted) may be implemented to the semiconductor structure 400. In one example, an etching process may be performed to selectively remove the nitride layer 406, such that the isolation features 432 and 434 may protrude from the oxide layer 404. Alternatively or additionally, photo-sensitive devices and/or transistors may be formed in one or both of the regions 402a and 402b adjacent to the isolation features 432 and/or 434.

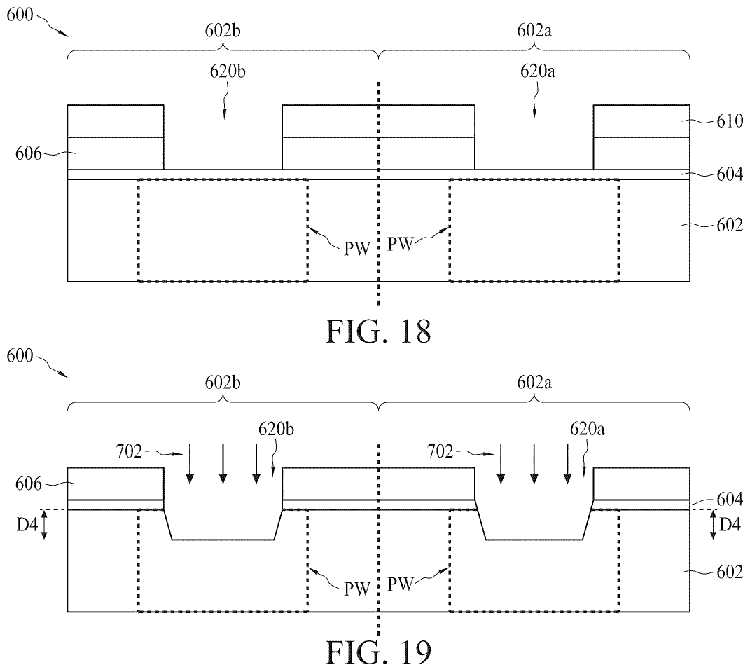

In some embodiments, FIGS. 18-23 illustrate schematic cross-sectional views of the semiconductor structure 600 at various stages of fabrication according to the methods 100 and 140.

Referring to FIGS. 9 and 18, the method 100 begins at operation 102 in which a substrate 602, including a region 602a and a region 602b, is provided in the semiconductor structure 600, where the substrate 602 is similar to the substrate 202 (or the substrate 402) as described in detail above. The substrate 602 may include a PW in each of the regions 602a and 602b. The method 100 continues to operations 104 and 106 in which an oxide layer 604 is formed over the substrate 602 and a nitride layer 606 is formed over the oxide layer 602, where the oxide layer 604 and the nitride layer 606 are similar to the oxide layer 204 (or the oxide layer 404) and the nitride layer 206 (or the nitride layer 406), respectively, as described in detail above.

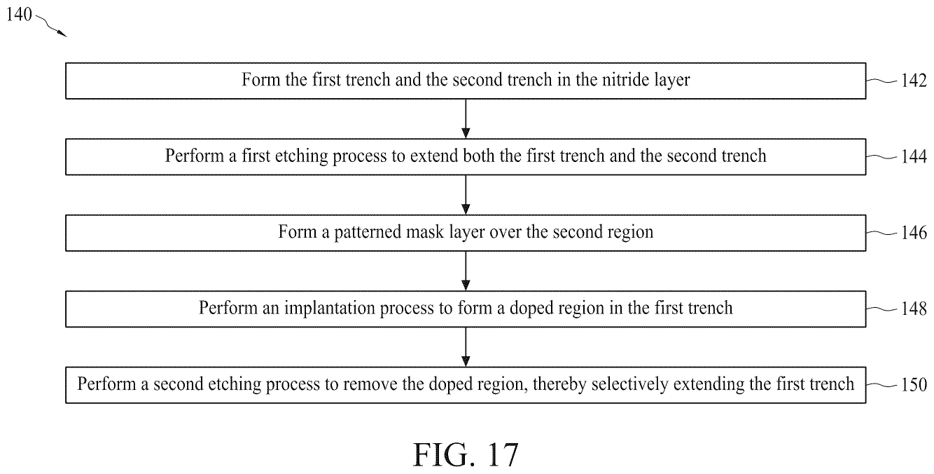

Referring to FIG. 9, the method 100 continues to operation 108 in which a trench 620a and a trench 620b are formed in the regions 602a and 602b, respectively. Operation 108 may be implemented by the method 140 described in FIGS. 17-23.

Referring to FIGS. 17 and 18, the method 140 begins with operation 142 in which the trenches 620a and 620b are formed in the nitride layer 606. The trenches 620a and 620b may be formed by a series of patterning and etching processes similar to those described above with respect to forming the trenches 420a and 420b. For example, forming the trenches 620a and 620b may include first forming a patterned mask layer 610, where the patterned mask layer 610 may be similar to the patterned mask layer 210 (or the patterned mask layer 410) in composition and formed in a manner similar to that described above. Subsequently, the exposed portions of the nitride layer 606 are removed by an etching process to form the trenches 620a and 620b in the regions 602a and 602b, respectively. Subsequently, the patterned mask layer 610 may be removed from the regions 602a and 602b by a suitable process, such as plasma ashing or resist stripping.

Referring to FIGS. 17 and 19, the method 140 continues to operation 144 in which an etching process 702 is performed to extend both the trenches 620a and 620b into the substrate 602.

In the present embodiments, the etching process 702 is similar to the etching process 506. For example, the etching process 702 is configured to remove portions of the substrate 602 (e.g., the PW) in the regions 602a and 602b, thereby downwardly extending both the trenches 620a and 620b into the substrate 602. In this regard, the etching process 702 is not selective towards either of the two regions 602a and 602b. As shown in FIG. 19, both of the trenches 620a and 620b are extended downward by a depth D4, such that the trenches 620a and 620b have the same depth after performing the etching process 702. The present embodiments do not limit the magnitude of the depth D4, which may be configured according to specific design requirements. In some embodiments, the depth D4 may be controlled by adjusting the duration of the etching process 702. In some embodiments, the etching process 702 is a dry etching process and may remove portions of the substrate 602 in a more anisotropic manner. In this regard, profile of each of the trenches 620a and 620b may be defined by tapered or slanted sidewalls rather than vertical sidewalls, such that the trenches 420a and 420b are each formed to an approximately inverted trapezoidal shape.

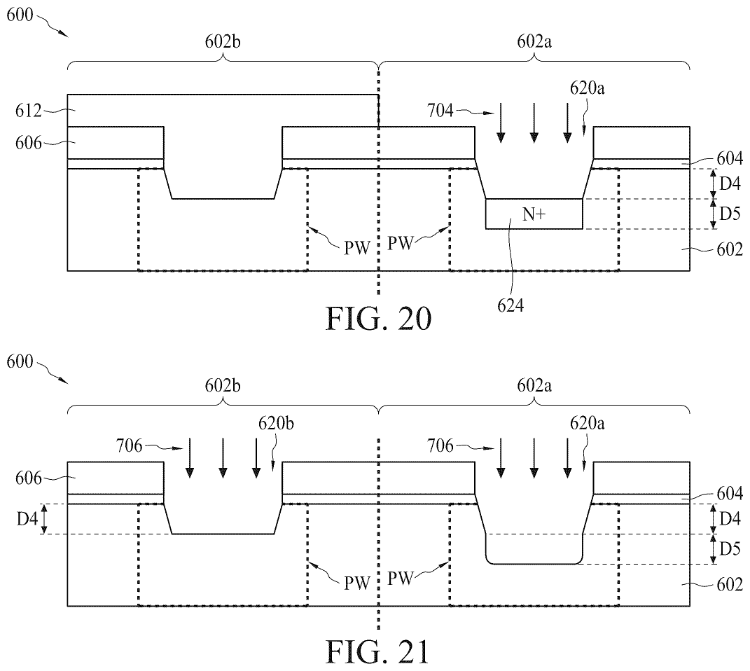

Referring to FIGS. 17 and 20, the method 140 continues to operation 146 in which a patterned mask layer 612 is selectively formed over the region 602b, thereby filling the trench 620b but exposing the trench 620a. The patterned mask layer 612 may be similar to the patterned mask layer 210 (or the patterned mask layer 410, 412) in composition and formed in a manner similar to that described above.

Still referring to FIGS. 17 and 20, the method 140 continues to operation 148 in which an implantation process 704 is performed to form a doped region 624 below the oxide layer 604 corresponding to the trench 620a.

In the present embodiments, the implantation process 704 is similar to the implantation process 302 (or the etching process 502) as described above. For example, the implantation process 704 may be an ion implantation process configured to dope the region 602a (e.g., in the PW of the substrate 602) with an n-type dopant, such as arsenic, phosphorous, antimony, the like, or combinations thereof. Various parameters (e.g., implantation energy, dosage of the dopant species, etc.) of the implantation process 704 may be similar to those of the implantation process 302 (or the etching process 502) described above. In some embodiments, the doped region 624 and the region 602b (e.g., including the PW) differ in the amount (or concentration) of the n-type dopant, such that an etching selectivity exists therebetween. The doped region 624 may be formed to a depth D5, which extends over a region of the substrate 602 below the oxide layer 604, such that the doped region 624 is formed at the depth D4 below the oxide layer 604. Similar to the doped region 224 (or the doped region 424), the depth D5 corresponds to the depth of a subsequently-formed trench in the substrate 602. Subsequently, the patterned mask layer 612 may be removed from the region 602b by a suitable process, such as plasma ashing or resist stripping.

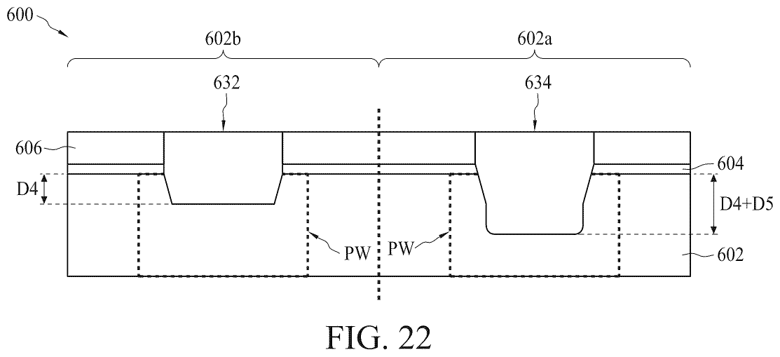

Referring to FIGS. 17 and 21, the method 140 continues to operation 150 in which an etching process 706 is performed to selectively remove the doped region 624 from the region 602a, thereby extending the trench 620a.

In the present embodiments, the etching process 706 is a selective etching process similar to the etching process 304 (or the etching process 504) as described above. For example, the etching process 706 is a chemical etching process (e.g., an RIE process) in which an etchant is applied to selectively react with and subsequently remove the doped region 624 without removing, or substantially removing, the surrounding portions of the substrate 602 (e.g., the PW). In this regard, the etching process 706 is configured to selectively remove the doped region 624 exposed in the trench 620a without etching, or substantially etching, the portion of the substrate 602 exposed in the trench 620b, thereby selectively extending the trench 620a into the substrate 602 in the region 602a by the depth D5.

Accordingly, a total depth of the trench 620a is a sum of the depths D4 and D5 and a total depth of the trench 620b is substantially equivalent to the depth D4. The present embodiments do not limit the magnitude of the depths D4 and D5, which may be configured according to specific design requirements.

As described in detail above with respect to the etching process 304 (or the etching process 504), the etching process 706 stops (or spontaneously stops) when the doped region 624 is consumed, such that the depth the extended trench 620a corresponds to the depth D5 of the doped region 624. The etching process 706 differs from the etching process 704, which may be controlled by adjusting the duration of the etching process.

Referring to FIGS. 9 and 22, the method 100 continues with operation 110 in which an isolation feature 632 is formed in the trench 620a and an isolation feature 634 is formed in the trench 620b.

The isolation features 632 and 634 may be similar to the isolation feature 232 (or the isolation features 432 and 434) in composition and formed in a manner similar to that described above. For example, forming the isolation features 632 and 634 may include depositing a dielectric layer over the semiconductor structure 600 to fill the trenches 620a and 620b and performing a CMP process to planarize a top surface of the dielectric layer with a top surface of the nitride layer 606. The resulting isolation feature 632 has a depth that is the sum of the depths D4 and D5 and the isolation feature 634 has a depth that is substantially equivalent to the depth D4.

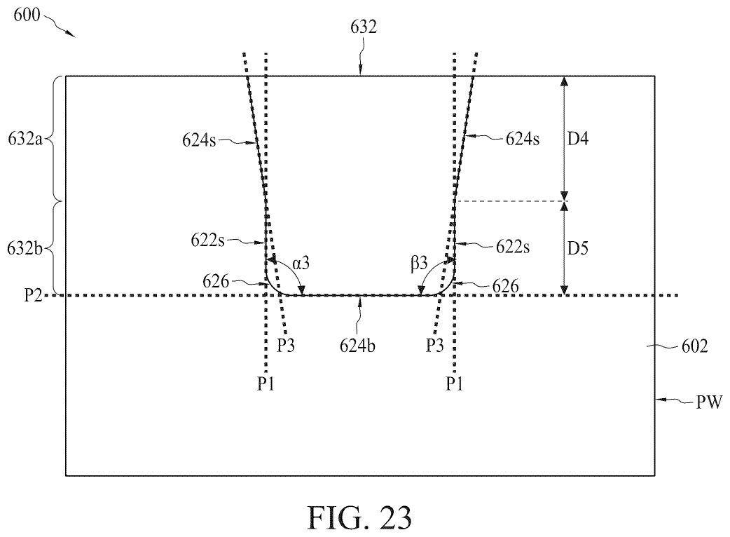

FIG. 23 is an enlarged view of a portion of the semiconductor structure 600 including the isolation feature 632 as shown in FIG. 22. The isolation feature 632 includes a top portion 632a over a bottom portion 632b having different sidewall profiles as a result of the different etching processes used to form them. For example, as provided herein, the top portion 632a is formed by the etching process 702, and the bottom portion 632b is formed by the etching process 706, which is similar to the etching process 304 (or the etching process 504). As the etching process 702 removes portions of the substrate 602 in both regions 602a and 602b in a more anisotropic manner, profile of the top portion 632a may be defined by slanted sidewalls 624s. In contrast, the etching process 706 is selective to remove the doped region 624 and not, or not substantially, the substrate 602, resulting in substantially vertical sidewalls 622s similar to the vertical sidewalls 422s (or the sidewalls 220s). As shown, the vertical sidewalls 622s extend along the plane P1, a bottom surface 624b extends along the plane P2, and slanted sidewalls 624s extend along the plane P3. In this regard, the planes P1 and P2 form an angle α3, which is approximately 90°, such that the vertical sidewalls 622s are substantially perpendicular to the bottom surface 624b of the isolation feature 632. An angle β3 between the planes P2 and P3 is approximately greater than 90°. In some embodiments, the top portion 632a laterally protrudes from the vertical sidewalls 622s, such that the isolation feature 632 laterally expands near a top surface of the top portion 632a. In some embodiments, the top portion 632a includes two bottom corners 626 that are rounded, similar to the corners 220c depicted in FIG. 6.

Referring to FIG. 9, the method 100 continues with operation 112 in which additional operations (not depicted) may be implemented to the semiconductor structure 600, similar to operation 112 implemented to the semiconductor structure 200 (or the semiconductor structure 400) described above.

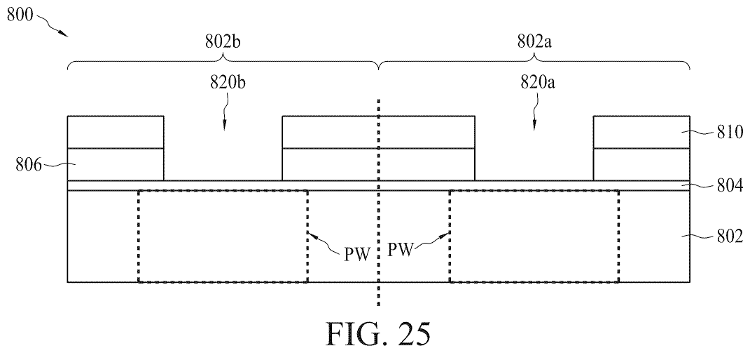

In some embodiments, FIGS. 25-31 illustrate schematic cross-sectional views of the semiconductor structure 800 at various stages of fabrication according to the methods 100 and 160.

Referring to FIGS. 9 and 25, the method 100 begins at operation 102 in which a substrate 802, including a region 802a and a region 802b, is provided in the semiconductor structure 800, where the substrate 802 is similar to the substrate 202 (or the substrate 402, 602) as described in detail above. The substrate 802 may include a PW in each of the regions 802a and 802b. The method 100 continues to operations 104 and 106 in which an oxide layer 804 is formed over the substrate 802 and a nitride layer 806 is formed over the oxide layer 804, where the oxide layer 804 and the nitride layer 806 are similar to the oxide layer 204 (or the oxide layer 404, 604) and the nitride layer 806 (or the nitride layer 406, 606), respectively, as described in detail above.

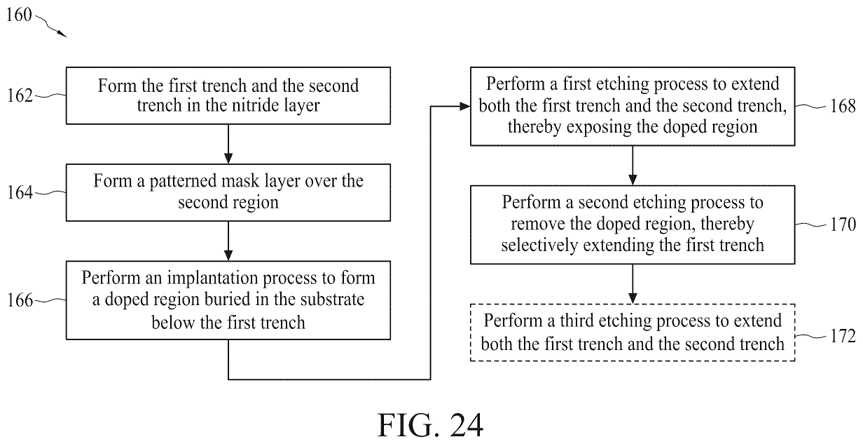

Referring to FIG. 9, the method 100 continues to operation 108 in which a trench 820a and a trench 820b are formed in the regions 802a and 802b, respectively. Operation 108 may be implemented by the method 160 described in FIGS. 24-31.

Referring to FIGS. 24 and 25, the method 160 begins with operation 162 in which the trenches 820a and 820b are formed in the nitride layer 806. The trenches 820a and 820b may be formed by a series of patterning and etching processes similar to those described above with respect to forming the trenches 420a and 420b. For example, forming the trenches 820a and 820b may include first forming a patterned mask layer 810, where the patterned mask layer 810 may be similar to the patterned mask layer 210 (or the patterned mask layer 410, 610) in composition and formed in a manner similar to that described above. Subsequently, the exposed portions of the nitride layer 806 are removed by an etching process to form the trenches 820a and 820b in the regions 802a and 802b, respectively. Subsequently, the patterned mask layer 810 may be removed from the regions 802a and 802b by a suitable process, such as plasma ashing or resist stripping.

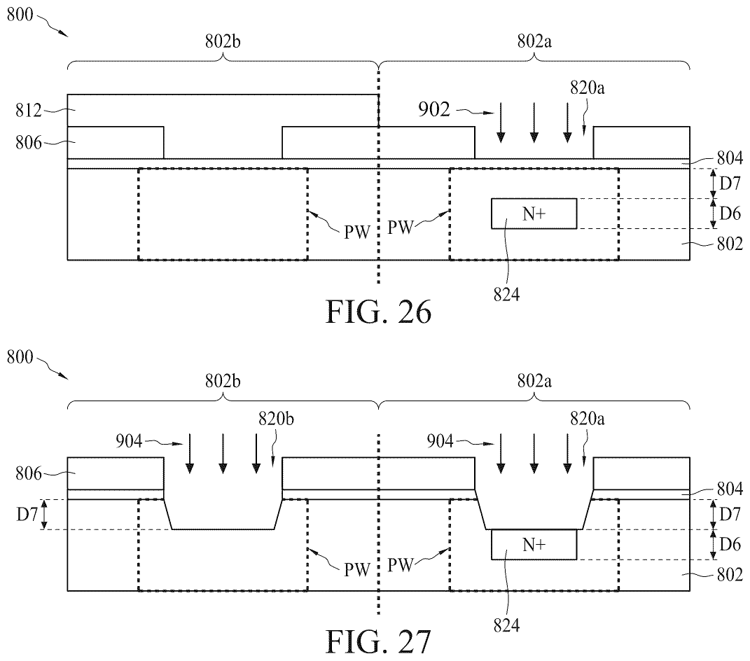

Referring to FIGS. 24 and 26, the method 160 continues with operation 164 in which a patterned mask layer 812 is selectively formed over the region 802b, thereby filling the trench 820b but exposing the trench 820a. The patterned mask layer 812 may be similar to the patterned mask layer 210 (or the patterned mask layer 410, 610) in composition and formed in a manner similar to that described above.

Referring to FIGS. 24 and 26, the method 160 continues with operation 166 in which an implantation process 902 is performed to form a doped region 824 below the oxide layer 804 corresponding to the trench 820a.

In the present embodiments, the implantation process 902 is similar to the implantation process 302 (or the implantation process 502, 704) as described above. For example, the implantation process 502 may be an ion implantation process configured to dope the region 802a (e.g., in the PW of the substrate 802) of a portion of the substrate 802 with an n-type dopant, such as arsenic, phosphorous, antimony, the like, or combinations thereof. In some embodiments, the doped region 824 and the region 802b (e.g., including the PW) differ in the amount (or concentration) of the n-type dopant, such that an etching selectivity exists therebetween.

In the present embodiments, the doped region 824 is formed to a depth D6, which extends over a region of the substrate 802 below the oxide layer 804. As shown, a separation distance between the doped region 824 and a top surface of the substrate 802 (or a bottom surface of the oxide layer 804) is defined by a depth D7. In this regard, parameters of the etching process 902 including, for example, the implantation energy, may be adjusted to ensure that the dopants are introduced at the depth D7 below the oxide layer 804. As described above with respect to the doped region 224 (or the doped region 424, 624), the depth D6 corresponds to the depth of a subsequently-formed trench in the substrate 802. Subsequently, the patterned mask layer 812 may be removed from the region 802b by a suitable process, such as plasma ashing or resist stripping.

Referring to FIGS. 24 and 27, the method 160 continues to operation 168 in which an etching process 904 is performed to extend both the trenches 820a and 820b into the substrate 802.

In the present embodiments, the etching process 904 is similar to the etching process 506 (or the etching process 702). For example, the etching process 904 is configured to remove portions of the substrate 802 (e.g., the PW), thereby downwardly extending both the trenches 820a and 820b into the substrate 802 to expose the doped region 824 in the region 802a. In this regard, the etching process 904 is not selective towards either of the two regions 802a and 802b. As shown in FIG. 27, both of the trenches 820a and 820b are extended downward by the depth D7, such that the trenches 820a and 820b have the same depth after performing the etching process 904. The present embodiments do not limit the magnitude of the depth D7, which may be configured according to specific design requirements. In some embodiments, the depth D7 may be controlled by adjusting the duration of the etching process 904, such that the etching process 904 continues until the doped region 824 is exposed in the trench 820a. In some embodiments, the etching process 904 is a dry etching process and may remove portions of the substrate 802 in a more anisotropic manner. In this regard, profile of each of the trenches 820a and 820b may be defined by tapered or slanted sidewalls rather than vertical sidewalls, such that the trenches 820a and 820b are each formed to an inverted trapezoidal shape.

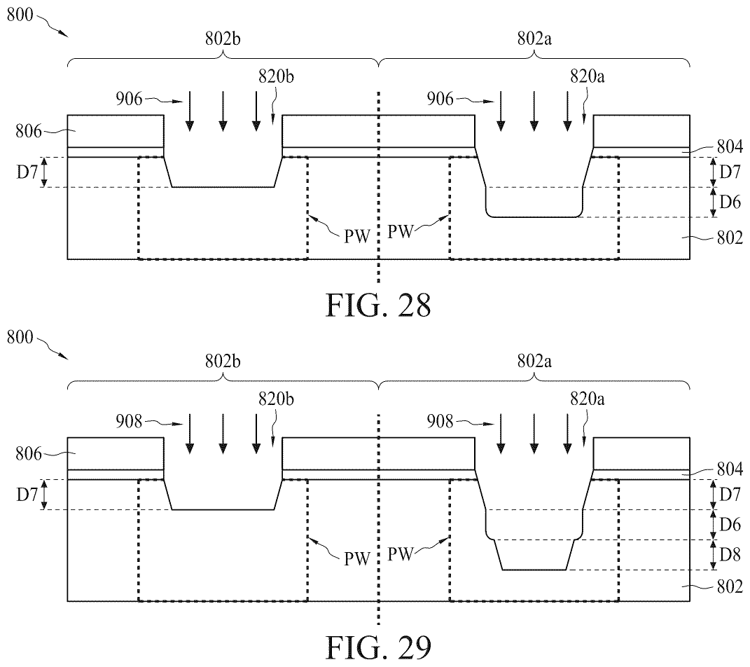

Referring to FIGS. 24 and 28, the method 160 continues with operation 170 in which an etching process 906 is performed to selectively remove the doped region 824 from the region 802a, thereby extending the trench 820a.

In the present embodiments, the etching process 906 is a selective etching process similar to the etching process 304 (or the etching process 502, 704) as described above. For example, the etching process 906 is a chemical etching process (e.g., an RIE process) in which an etchant is applied to selectively react with and subsequently remove the doped region 824 without removing, or substantially removing, the surrounding portions of the substrate 802 (e.g., the PW). In this regard, the etching process 906 is configured to selectively remove the doped region 824 exposed in the trench 820a without etching, or substantially etching, the portion of the substrate 802 exposed in the trench 820b, thereby selectively extending the trench 820a into the substrate 802 in the region 802a by the depth D6. Similar to the etching process 304, the etching process 906 stops (or spontaneously stops) when the doped region 824 is consumed, such that a total depth of the trench 820a corresponds to a sum of the depths D6 and D7. A profile of the resulting trench 820a is similar to that depicted and described with respect to FIG. 21.

Referring to FIGS. 24 and 29, the method 160 continues to operation 172 in which an etching process 908 is performed to extend both the trenches 820a and 820b into the substrate 802 by a depth D8. The etching process 902 may be similar to the etching process 904 as described above and is therefore not selective towards either of the two regions 802a and 802b. In some embodiments, the etching process 908 is optional.

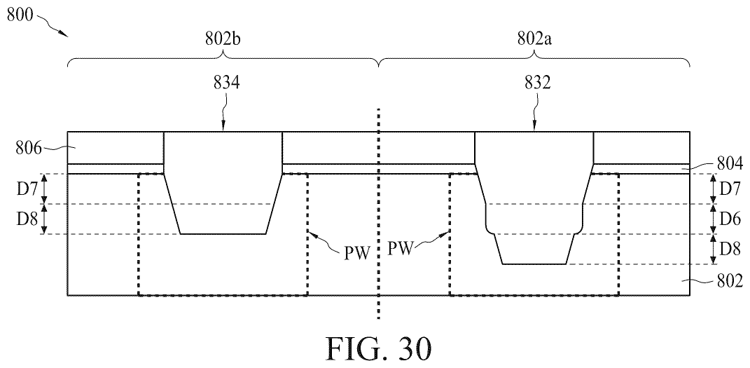

Referring to FIGS. 9 and 30, the method 100 continues with operation 110 in which an isolation feature 832 is formed in the trench 820a and an isolation feature 834 is formed in the trench 820b.

The isolation features 832 and 834 may be similar to the isolation feature 232 (or the isolation features 432 and 434, 632 and 634) in composition and formed in a manner similar to that described above. For example, forming the isolation features 832 and 834 may include depositing a dielectric layer over the semiconductor structure 800 to fill the trenches 820a and 820b and performing a CMP process to planarize a top surface of the dielectric layer with a top surface of the nitride layer 806. The resulting isolation feature 832 has a depth that is the sum of the depths D6, D7, and D8, and the isolation feature 834 has a depth that is substantially equivalent to a sum of the depth D7 and D8.

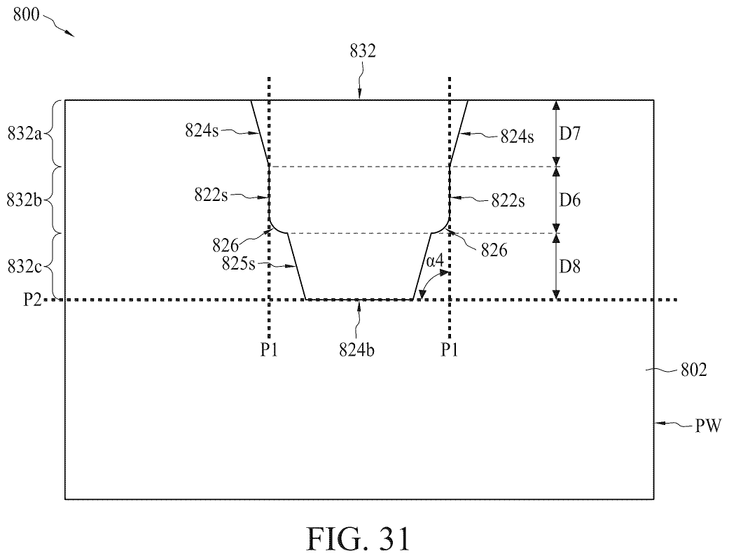

FIG. 31 is an enlarged view of a portion of the semiconductor structure 800 including the isolation feature 832 as shown in FIG. 30. The isolation feature 832 includes a top portion 832a over a middle portion 832b, which is over a bottom portion 832c, where the isolation feature 832 includes different sidewall profiles as a result of the different etching processes used to form them. For example, the top portion 832a may be formed by the etching process 904, the middle portion 832b may be formed by the etching process 906, which is similar to the etching process 304 (or the etching process 504, 706), and the bottom portion 832c may be formed by the etching process 908. As the etching processes 904 and 908 respectively remove portions of the substrate 802 in a more anisotropic manner, profile of the top portion 832a and the bottom portion 832c may be defined by slanted sidewalls 824s and 825s, respectively. In contrast, the etching process 906 is selective to remove the doped region 824 with respect to the substrate 802, resulting in substantially vertical sidewalls 822s similar to the vertical sidewalls 422s (or 622s). As shown, the vertical sidewalls 822s extend along the plane P1 and a bottom surface 824b extends along the plane P2. In this regard, the planes P1 and P2 form an angle α4, which is approximately 90°, such that the vertical sidewalls 822s are substantially perpendicular to the bottom surface 824b of the isolation feature 832. In some embodiments, the slanted sidewalls 824s and 825s have different degrees of slant with respect to the plane P1. In some examples, the middle portion 832b may laterally protrude beyond the slanted sidewalls 825s, such that the isolation feature 832 laterally expands near the middle of the isolation feature 832. In some embodiments, the middle portion 832a includes two rounded corners 826 similar to the corners 220c depicted in FIG. 6. In this regard, the slanted sidewall 825s and the vertical sidewall 822s meet at one of the rounded corners 826.

Referring to FIG. 9, the method 100 continues with operation 112 in which additional operations (not depicted) may be implemented to the semiconductor structure 800, similar to operation 112 implemented to the semiconductor structure 200 (or the semiconductor structures 400, 600) described above.

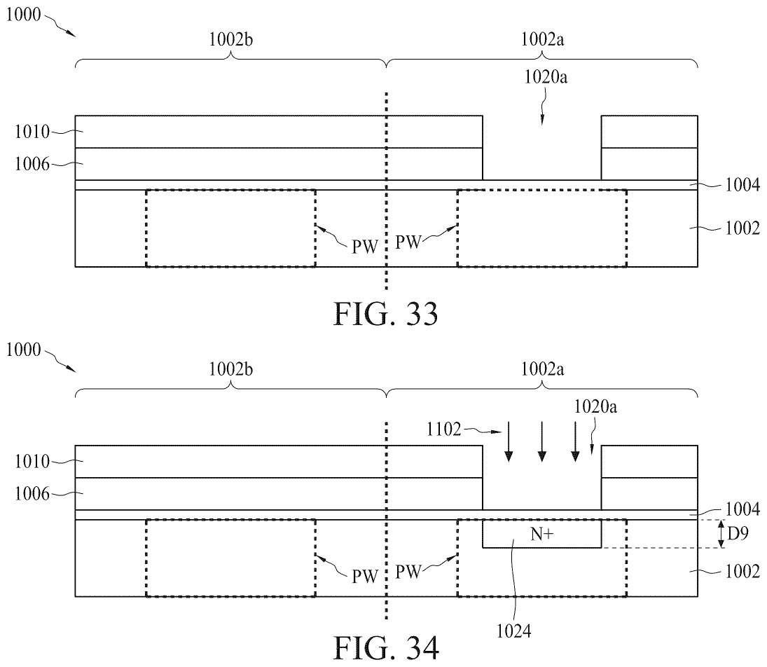

In some embodiments, FIGS. 33-39 illustrate schematic cross-sectional views of the semiconductor structure 1000 at various stages of fabrication according the methods 100 and 180.

Referring to FIGS. 9 and 33, the method 100 begins at operation 102 in which a substrate 1002, including a region 1002a and a region 1002b, is provided in the semiconductor structure 1000, where the substrate 1002 is similar to the substrate 202 (or the substrate 402, 602, 802) as described in detail above. The substrate 1002 may include a PW in each of the regions 1002a and 1002b. The method 100 continues to operations 104 and 106 in which an oxide layer 1004 is formed over the substrate 1002 and a nitride layer 1006 is formed over the oxide layer 1004, where the oxide layer 1004 and the nitride layer 1006 are similar to the oxide layer 204 (or the oxide layer 404, 604, 804) and the nitride layer 206 (or the nitride layer 406, 606, 806), respectively, as described in detail above.

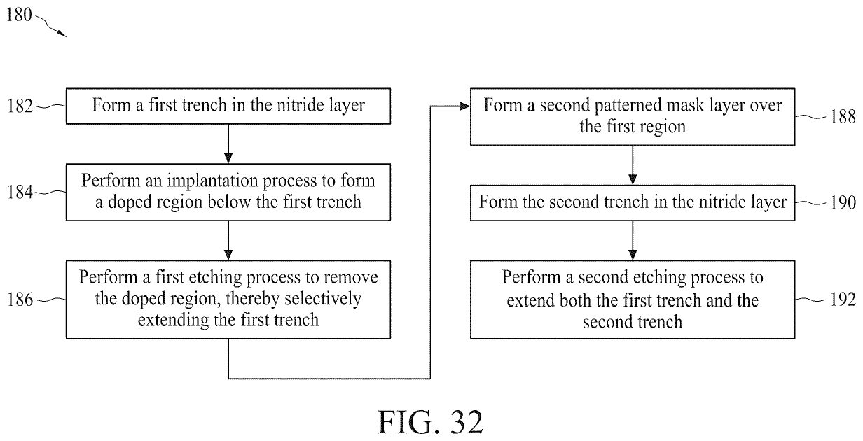

Referring to FIG. 32, the method 100 continues to operation 108 in which a trench 1020a and a trench 1020b are formed in the regions 1002a and 1002b, respectively. Operation 108 may be implemented by the method 180 described in FIGS. 32-38.

Referring to FIGS. 32 and 33, the method 180 begins with operation 182 in which a trench 1020a is formed in the nitride layer 1006 in the region 1002a. The trench 1020a may be formed by a series of patterning and etching processes similar to those described above with respect to forming the trenches 420a and 420b. For example, forming the trench 1020a may include first forming a patterned mask layer 1010, where the patterned mask layer 1010 may be similar to the patterned mask layer 210 (or the patterned mask layer 410, 610, 810) in composition and formed in a manner similar to that described above. In the present embodiments, the patterned mask layer 1010 exposes a portion of the nitride layer 1006 by an opening in the region 1002a but covers a portion of the nitride layer 1006 in the region 1002b. Subsequently, the exposed portion of the nitride layer 1006 is removed by an etching process to form the trench 1020a in the region 1002a.

Referring to FIGS. 32 and 34, the method 180 continues to operation 184 in which an implantation process 1102 is performed to form a doped region 1024 below the oxide layer 1004 corresponding to the trench 1020a with the patterned mask layer 1010 remaining over the nitride layer 1006.

In the present embodiments, the implantation process 1102 is similar to the implantation process 302 (or the etching processes 502, 704, 902) as described above. For example, the implantation process 1102 may be an ion implantation process configured to dope the region 1002a (e.g., in the PW of the substrate 1002) with an n-type dopant, such as arsenic, phosphorous, antimony, the like, or combinations thereof. Various parameters (e.g., implantation energy, dosage of the dopant species, etc.) of the implantation process 1102 may be similar to those of the implantation process 302 (or the etching processes 502, 704, 902) described above. In some embodiments, the doped region 1024 and the region 1002b (e.g., including the PW) differ in the amount (or concentration) of the n-type dopant, such that an etching selectivity exists therebetween. The doped region 1024 may be formed to a depth D9, which extends over a region of the substrate 1002 below the oxide layer 1004. Similar to the doped region 242 (or the doped region 424, 624, 824), the depth D9 corresponds to the depth of a subsequently-formed trench in the substrate 1002. Subsequently, the patterned mask layer 1010 may be removed from the regions 1002a and 1002b by a suitable process, such as plasma ashing or resist stripping.

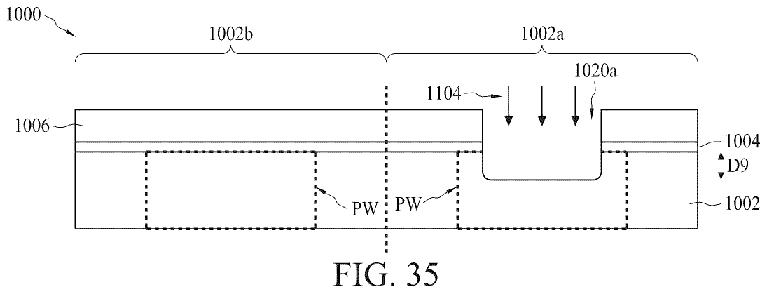

Referring to FIGS. 32 and 35, the method 180 continues to operation 186 in which an etching process 1104 is performed to selectively remove the doped region 1024 from the region 1002a, thereby extending the trench 1020a.

In the present embodiments, the etching process 1104 is a selective etching process similar to the etching process 304 (or the etching processes 504, 706, 906) as described above. For example, the etching process 1104 is a chemical etching process (e.g., an RIE process) in which an etchant is applied to selectively react with and subsequently remove the doped region 1024 without removing, or substantially removing, the surrounding portions of the substrate 1002 (e.g., the PW). In this regard, the etching process 1104 is configured to selectively remove the doped region 1024 exposed in the trench 1020a without etching, or substantially etching, the portion of the substrate 1002 in the region 1002b, thereby selectively extending the trench 1020a into the substrate 1002 in the region 1002a by the depth D9. A profile of the resulting trench 1020a is similar to that depicted and described with respect to FIG. 6 (or FIG. 13).

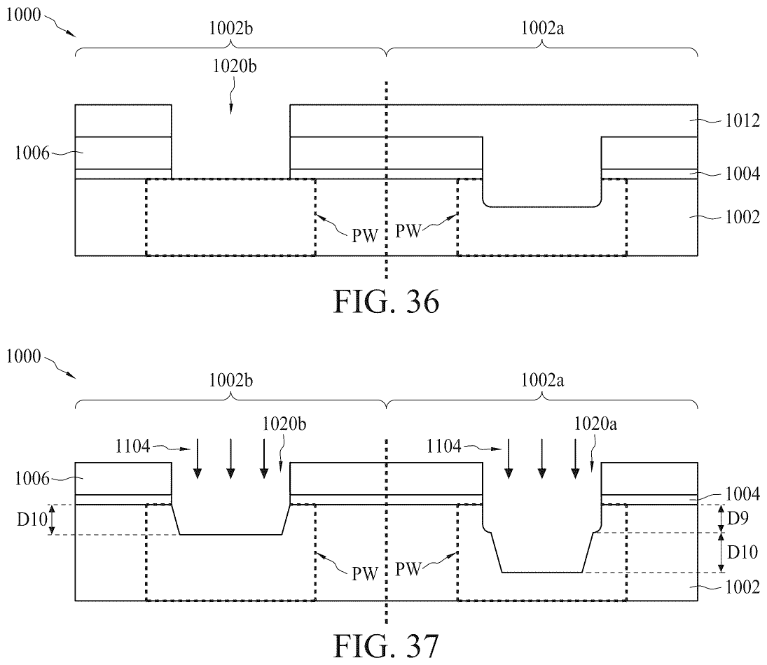

Referring to FIGS. 32 and 36, the method 180 continues to operation 188 in which a patterned mask layer 1012 is selectively formed over the region 1002a, thereby filling the trench 1020a and exposing a portion of the nitride layer 1006 in the region 1002b. The patterned mask layer 1012 may be similar to the patterned mask layer 210 (or the patterned mask layer 410, 610, 810) in composition and formed in a manner similar to that described above. A trench 1020b is subsequently formed in the nitride layer 1006 in the region 1002b using the patterned mask layer 1012 as an etch mask. The patterned mask layer 1012 may be removed from the regions 1002a and 1002b by a suitable process, such as plasma ashing or resist stripping.

Referring to FIGS. 32 and 37, the method 180 continues to operation 190 in which an etching process 1104 is performed to extend both the trenches 1020a and 1020b into the substrate 1002.

In the present embodiments, the etching process 1104 is similar to the etching process 506 (or the etching processes 702, 904, 908). For example, the etching process 1104 is configured to remove portions of the substrate 1002 (e.g., the PW) in the regions 1002a and 1002b, thereby downwardly extending both the trenches 1020a and 1020b into the substrate 1002. In this regard, the etching process 1104 is not selective towards either of the two regions 1002a and 1002b. As shown in FIG. 37, both of the trenches 1020a and 1020b are extended downwardly by a depth D10, such that the trench 1020a has a depth that is a sum of the depths D9 and D10, and the trench 1020b has a depth that is substantially equivalent to the depth D10 after performing the etching process 1104. The present embodiments do not limit the magnitude of the depths D9 and D10, which may be configured according to specific design requirements. In some embodiments, the depth D10 may be controlled by adjusting the duration of the etching process 1104. In some embodiments, the etching process 1104 is a dry etching process and may remove portions of the substrate 1002 in a more anisotropic manner. In this regard, profile of the trench 1020b and a bottom portion of the trench 1020a may each be defined by tapered or slanted sidewalls rather than vertical sidewalls, resulting in an inverted trapezoidal shape.

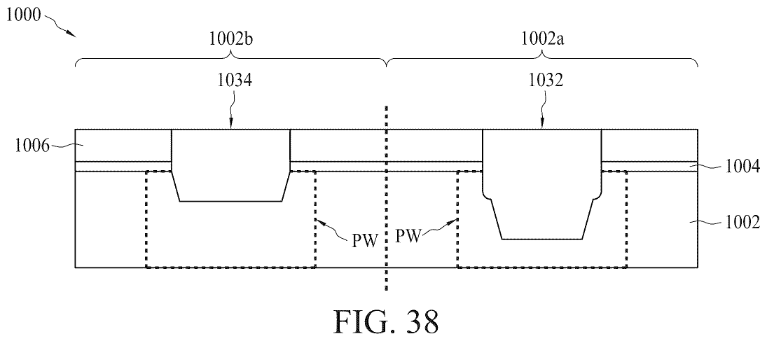

Referring to FIGS. 9 and 38, the method 100 continues with operation 110 in which an isolation feature 1032 is formed in the trench 1020a and an isolation feature 1034 is formed in the trench 1020b.

The isolation features 1032 and 1034 may be similar to the isolation feature 232 (or the isolation features 432 and 434, 632 and 634, or 832 and 834) in composition and formed in a manner similar to that described above. For example, forming the isolation features 1032 and 1034 may include depositing a dielectric layer over the semiconductor structure 1000 to fill the trenches 1020a and 1020b and performing a CMP process to planarize a top surface of the dielectric layer with a top surface of the nitride layer 1006. The resulting isolation feature 1032 has a depth that is the sum of the depths D9 and D10 and the isolation feature 1034 has a depth that is substantially equivalent to the depth D10.

Referring to FIG. 9, the method 100 continues with operation 112 in which additional operations (not depicted) may be implemented to the semiconductor structure 1000, similar to operation 112 implemented to the semiconductor structure 200 (or the semiconductor structure 400, 600, 800) described above.

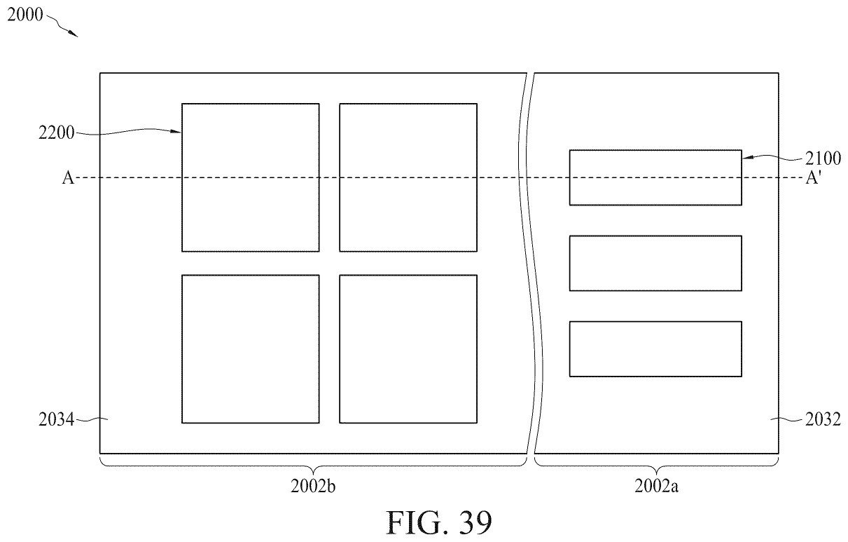

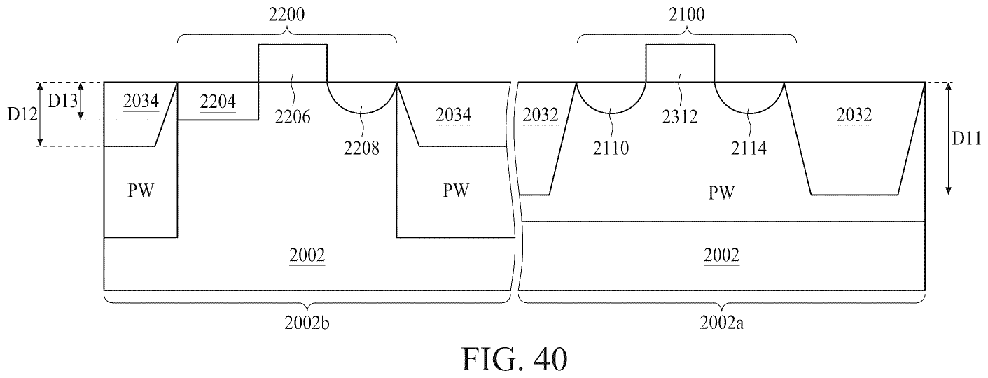

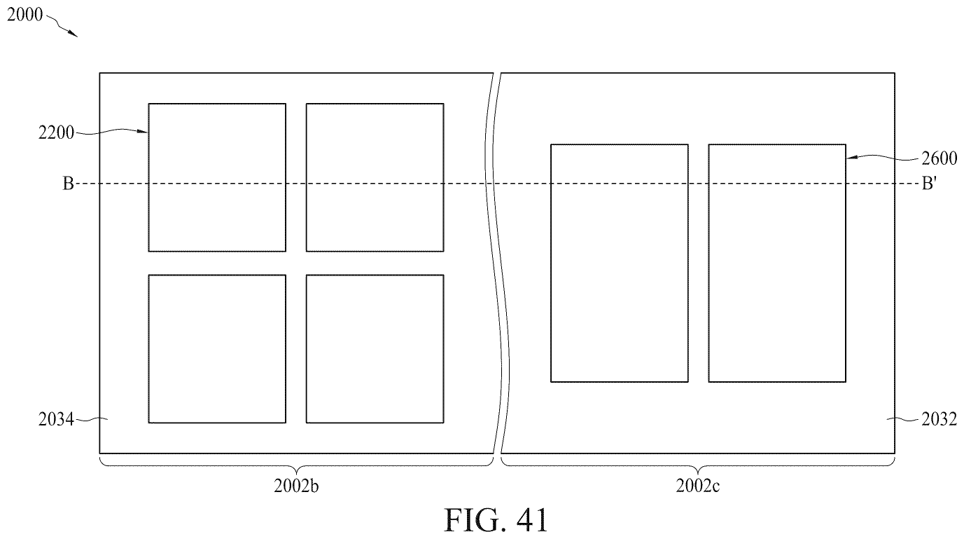

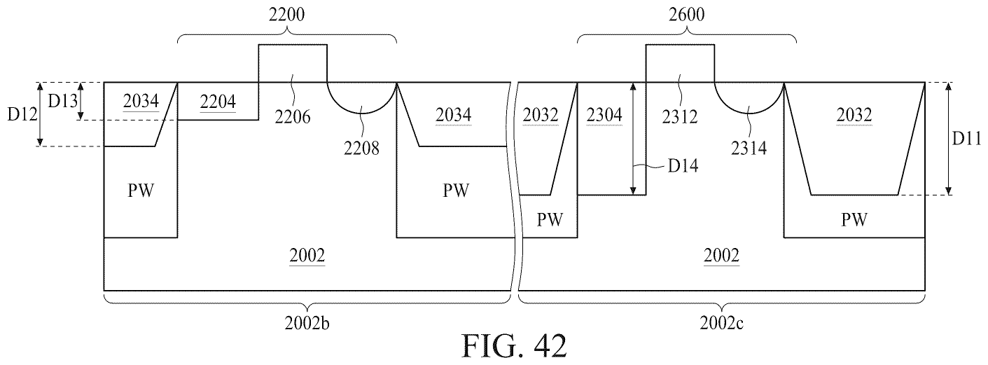

In some embodiments, referring to FIGS. 39-44 collectively, the present disclosure provides semiconductor structures configured as charge-sensitive devices or image sensors, such as CISs, that include isolation features, such as STI structures, with different depths. FIGS. 39, 41, 43, and 44 are schematic top views of a semiconductor structure 2000; FIG. 40 is a schematic cross-sectional view of the semiconductor structure 2000 along line AA′ as shown in FIG. 39; and FIG. 42 is a schematic cross-sectional view of the semiconductor structure 2000 along line BB′ as shown in FIG. 41. It should be understood that the semiconductor structure 2000 is simplified for illustration purposes, and thus, the semiconductor structure 2000 can include any of various other components, while remaining within the scope of the present disclosure.

Referring to FIGS. 39 and 40, an embodiment of the semiconductor structure 2000 includes a substrate 2002 having a region 2002a and a region 2002b. In some embodiments, the semiconductor structure 2000 is an image sensor, where the region 2002b is a pixel region of the image sensor and the region 2002a is a peripheral circuit region of the image sensor. In general, the pixel region may include a number of image sensing elements, such as photo-sensitive elements (e.g., photodiodes) and transistors (e.g., transfer gate transistors, reset transistors), and the peripheral circuit region may include a number of transistors and other devices used as control and signal circuits. In some embodiments, the regions 2002a and 2002b are electrically coupled to one another. In some embodiments, the semiconductor structure 2000 includes additional regions disposed between the regions 2002a and 2002b.

As shown in FIG. 39, the semiconductor structure 2000 includes isolation features (e.g., a first STI structure) 2032 over the region 2002a and isolation features (e.g., a second STI structure) 2034 over the region 2002b, where the isolation features 2032 are formed to separate and surround devices over the region 2002a and the isolation features 2034 are formed to separate and surround devices over the region 2002b. In some embodiments, the region 2002b includes an array of pixel units 2200 each having at least a photo-sensitive (e.g., photo-receiving) element (e.g., a photodiode) over the substrate 2002 and the region 2002a includes one or more logic devices (e.g., transistors) 2100 over the substrate 2002. It is understood that a number of the pixel units 2200 and a number of the logic devices 2100 are not limited as such in FIG. 39.

Referring to FIG. 40, over the substrate 2002 the isolation features 2032 and 2034 are formed to define various devices or components within each of the regions 2002a and 2002b, respectively. For example, in the region 2002b, the pixel unit 2200 includes a photo-sensitive element (PD; alternatively referred to as a photo-sensitive device or a photodiode) 2204 configured to generate electron-hole pairs (EHPs) from light incident thereon, a transfer gate terminal 2206 coupled to the PD 2204, and a floating diffusion region 2208 coupled to the transfer gate terminal 2206. Furthermore, the isolation features 2034 are formed on both sides of (e.g., surrounding) the pixel unit 2200 and may be configured to isolate the pixel unit 2200 from an adjacent device region (e.g., the region 2002a) or another repeating pixel unit 2200. In some embodiments, the isolation features 2034 are formed in a p-well (PW) of the substrate 2002.

The semiconductor structure 2000, in the region 2002a, may include various semiconductor devices, for example, for removing noise from the output signal of the pixel region or for converting an analog signal into a digital signal. In the illustrated example of FIG. 40, however, the region 2002a is shown to include the logic device 2100 for purposes of simplicity. The logic device 2100 may be a transistor constituted by a gate terminal 2112 coupled to source/drain regions 2110 and 2114. The isolation features 2032 may be formed in the PW of the substrate 2002 in the region 2002a, where the PW may extend laterally from one isolation feature 2032 to an adjacent isolation feature 2032.

Referring to FIGS. 41 and 42, an embodiment of the semiconductor structure 2000 includes the substrate 2002 having the region 2002b and a region 2002c. In some embodiments, the region 2002c is different from the region 2002a of FIGS. 39 and 40 in that the region 2002c is another pixel region that includes a number of image sensing elements that are different from those of the region 2002b. For example, the region 2002b includes image sensing elements configured to detect light of a first wavelength (e.g., visible) and the region 2002c may include image sensing elements configured to detect light of a second wavelength (e.g., IR) different from the first wavelength. In this regard, the region 2002c includes an array of pixel units 2600 and the region 2002b includes an array of the pixel units 2200. In some embodiments, the regions 2002b and 2002c are electrically coupled to one another. In some embodiments, the semiconductor structure 2000 includes additional regions disposed between the regions 2002b and 2002c.

Referring to FIG. 41, which is similar to FIG. 39, the isolation features 2032 over the region 2002c are formed to separate and surround an array of pixel units 2600, while the isolation features 2034 over the region 2002b are formed to separate and surround the array of pixel units 2200. It is understood that a number of the pixel units 2200 and a number of the pixel units 2600 are not limited as such in FIG. 41.

Referring to FIG. 42, which is similar to FIG. 40, the isolation features 2032 and 2034 are formed to define various devices or components within each of the regions 2002c and 2002b, respectively. For example, in the region 2002c, the pixel unit 2600 includes a PD 2304 electrically coupled to a transfer gate terminal 2312, and a floating diffusion region 2314 coupled to the transfer gate terminal 2312. The isolation features 2302 are formed in the PW of the substrate 2002 and on both sides of the pixel unit 2600.

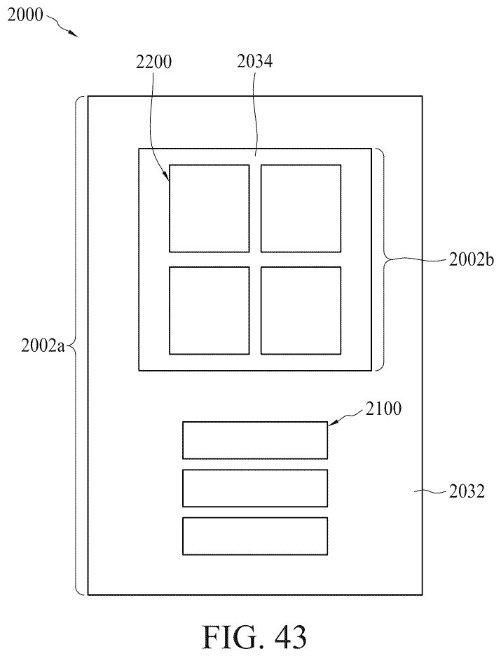

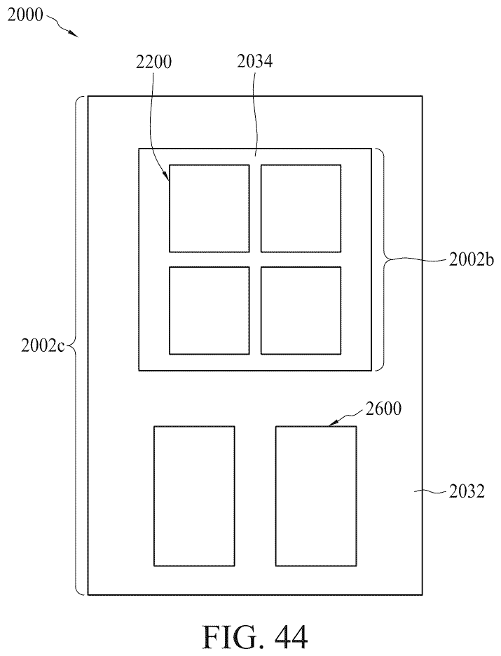

In some embodiments, the regions 2002b and 2002a (or 2002c) are arranged in a nested configuration. As shown in FIG. 43, the region 2002b, which includes the array of the pixel units 2200 surrounded by the isolation features 2034 may be nested within the isolation features 2032, which also surrounds the array of the logic devices 2100 to form the region 2002a. As shown in FIG. 44, the region 2002b may be nested within the isolation features 2032, which also surrounds the array of the pixel units 2600 to form the region 2002c.

In some embodiments, though not depicted, the semiconductor structure 2000 includes the regions 2002a and 2002c, coupled or separated, over the substrate 2002. In some embodiments, though not depicted, the semiconductor structure 2000 includes the regions 2002a, 2002b, and 2002c, coupled and/or separated, over the substrate 2002.

In the present embodiments, the substrate 2002 corresponds to any of the substrates 202, 402, 602, 802, or 1002 described in detail above with respect to composition and structure, where the region 2002a corresponds to any of the regions 402a, 602a, 802a, and 1002a, and the region 2002b corresponds to any of the regions 402b, 602b, 802b, and 1002b described in detail above. Accordingly, the isolation feature 2032 formed in the region 2002a corresponds to any of the isolation features 232, 432, 632, 832, and 1032 with respect to the structure and the method of formation, and the isolation feature 2034 formed in the region 2002b corresponds to any of the isolation features 434, 634, 834, and 1034 with respect to the structure and the method of formation as described in detail above.

In this regard, referring to FIGS. 40 and 42, the isolation feature 2032 is defined by a depth D11 that may be greater than a depth D12, which defines a depth of the isolation feature 2034. In some non-limiting examples, a ratio of the depth D11 to the depth D12 may be about 2 to about 2.7. In some embodiments, the PD 2204 has a depth D13 that may be less than the depth D12. In some non-limiting examples, a ratio of the depth D12 to the depth D13 may be about 1.5. In some embodiments, the PD 2304 has a depth D14 that may be greater than or equal to the depth D11. In some non-limiting examples, a ratio of the depth D14 to the depth D11 may be about 1 to about 1.7. It is noted that such dimensions and their ratios are for illustration purposes only and are not meant to limit the embodiments of the present disclosure.

In some embodiments, keeping the depth D12 at a minimal value reduces occurrence (or magnitude) of dark current (e.g., current leakage) for the PD 2204, thereby improving the performance thereof. Additionally, forming trenches for the isolation features 2032 and/or 2034 according to one or more of the methods 10, 100, 120, 140, 160, and 180, which include at least the step of implementing an implantation process (e.g., operations 20, 126, 148, 166, or 184) and the step of implementing a selective (e.g., chemical-based) etching process (e.g., operations 22, 128, 150, 168, or 186), may result in trenches having more vertical (or less slanted) sidewalls, incurring less damage (e.g., over-etching) to the surrounding substrate and thereby reducing current leakage of the device. In some embodiments, with the depth D11 being greater than the depth D12, crosstalk between devices (e.g., the logic device 2110) separated by the isolation features 2032 is reduced, thereby improving the overall performance of the semiconductor structure 2000. In this regard, the present embodiments provide methods of forming semiconductor structures having both shallow isolation features 2034 and deep isolation features 2032 (e.g., having a dual-STI structure) to improve device performance by reducing both dark current and crosstalk between various devices (or components).

In one aspect of the present disclosure, a semiconductor device is disclosed. The semiconductor device includes a substrate having a first device and a second device, where at least one of the first device and the second device includes a photo-sensitive element. The semiconductor device includes a first isolation feature surrounding the first device, where the first isolation feature has a first depth. The semiconductor device includes a second isolation feature surrounding the second device, where the second isolation feature has a second depth and where the first depth is greater than the second depth.

In another aspect of the present disclosure, a method for fabricating semiconductor devices is disclosed. The method includes providing a semiconductor substrate having a first region and a second region separated from the first region. The method includes performing an ion implantation process to selectively form a doped layer in the first region. The method includes performing a first etching process to selectively remove the doped layer. The method includes performing a second etching process to remove portions of the semiconductor substrate in the first region and the second region, where at least one of the first etching process and the second etching process forms a first trench having a first depth in the first region and a second trench having a second depth in the second region, wherein the first depth is greater than the second depth. The method further includes forming a first isolation structure to fill the first trench and a second isolation structure to fill the second trench

In yet another aspect of the present disclosure, a method for fabricating semiconductor devices is disclosed. The method includes performing a dry etching process to form a first trench and a second trench separated from one another in a substrate, where the first trench and the second trench each have a first depth. The method includes performing an ion implantation process to a bottom portion of the first trench. The method includes performing a chemical etching process to selectively extend the first trench to a second depth that is greater than the first depth. The method further includes forming a first isolation structure in the first trench and a second isolation structure in the second trench, such that the first isolation structure has the second depth and the second isolation structure has the first depth.

As used herein, the terms “about” and “approximately” generally mean±10% of the stated value. For example, about 0.5 would include 0.45 to 0.55, about 10 would include 9 to 11, about 1000 would include 900 to 1100.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate including a first device and a second device;
a first isolation feature surrounding the first device, the first isolation feature having a first depth; and
a second isolation feature surrounding the second device, the second isolation feature having a second depth, wherein the first depth is greater than the second depth, wherein the second isolation feature is nested in the first isolation feature, and wherein the first isolation feature and the second isolation feature are disposed in a doped region of the substrate.

2. The semiconductor device of claim 1, wherein at least one of the first device and the second device includes a photo-sensitive element.

3. The semiconductor device of claim 1, wherein a ratio of the first depth to the second depth is at least 2.

4. The semiconductor device of claim 1, wherein the first device includes a first photodiode configured to detect infrared (IR) light and the second device includes a second photodiode configured to detect visible light.

5. The semiconductor device of claim 1, wherein the first device includes a transistor and the second device includes a photodiode.

6. The semiconductor device of claim 1, wherein the doped region of the substrate includes a p-type dopant.

7. The semiconductor device of claim 1, wherein a sidewall of the first isolation feature includes a slanted portion connected to a vertical portion.

8. The semiconductor device of claim 7, wherein the slanted portion and the vertical portion meet at a rounded corner.

9. A method, comprising:
providing a semiconductor substrate having a first region and a second region separated from the first region;
forming a hard mask layer over the semiconductor substrate;
patterning the hard mask layer to form a first opening in the first region and a second opening in the second region;
forming a patterned mask layer to fill the second opening; and
performing an ion implantation process on the semiconductor substrate through the first opening to selectively form a doped layer in the first region.

10. The method of claim 9, further comprising:
performing a first etching process to selectively remove the doped layer;
performing a second etching process to remove portions of the semiconductor substrate in the first region and the second region, wherein at least one of the first etching process or the second etching process forms a first trench having a first depth in the first region and a second trench having a second depth in the second region, and wherein the first depth is greater than the second depth; and
forming a first isolation structure to fill the first trench and a second isolation structure to fill the second trench.

11. The method of claim 10, wherein the first etching process is performed before performing the second etching process.

12. The method of claim 10, wherein the second etching process is performed before performing the ion implantation process.

13. The method of claim 10, further comprising performing a third etching process before performing the ion implantation process, wherein the third etching process removes portions of the semiconductor substrate in the first region and the second region to form the first trench and the second trench, respectively, and wherein the doped layer is selectively formed in the first trench.

14. The method of claim 9, wherein the doped layer is buried in the semiconductor substrate.

15. The method of claim 9, wherein the performing the ion implantation process includes doping the semiconductor substrate with an n-type dopant.

16. The method of claim 10, wherein the performing the first etching process includes applying an etchant that includes chlorine, bromine, or a combination thereof.

17. A method, comprising:
performing a dry etching process to form a first trench and a second trench separated from one another in a substrate, the first trench and the second trench each having a first depth;
forming a patterned mask layer to fill the second trench;
performing an ion implantation process to a bottom portion of the first trench; and
performing a chemical etching process to selectively extend the first trench to a second depth that is greater than the first depth.

18. The method of claim 17, further comprising forming a first isolation structure in the first trench and a second isolation structure in the second trench, such that the first isolation structure has the second depth and the second isolation structure has the first depth.

19. The method of claim 17, wherein the dry etching process is a first dry etching process, the method further comprising performing a second dry etching process after performing the chemical etching process to extend the first trench and the second trench by a same amount.

20. The method of claim 17, wherein the performing the ion implantation process includes doping the bottom portion of the first trench with an n-type dopant.
